(19) United States
(12) Patent Application Publication
(10) Pub. No.: US 2013/0334507 A1
(43) Pub. Date: Dec. 19, 2013

(54) Organic EL Light Emitting Device and Manufacturing Method Thereof

(71) Applicant: ROHM CO., LTD., Kyoto (JP)

(72) Inventors: Noriyuki SHIMOJI, Kyoto (JP); Hiroaki SHIRAGA, Kyoto (JP); Tatsuya SUZUKI, Kyoto (JP); Masashi MATSUSHITA, Kyoto (JP); Keisuke NII, Kyoto (JP)

(21) Appl. No.: 13/904,796

(22) Filed: May 29, 2013

(30) Foreign Application Priority Data
May 30, 2012 (JP) 2012-122986
Jun. 6, 2012 (JP) 2012-128683
Jun. 11, 2012 (JP) 2012-132136
May 16, 2013 (JP) 2013-103909

(51) Int. Cl. F21V 9/08; H01L 51/56; H01L 51/50

(52) U.S. Cl. CPC F21V 9/08; H01L 51/5036; H01L 51/56
USPC 257/40; 359/891; 438/29

(57) ABSTRACT

There is provided a layered color filter which can improve optical selectivity, without reducing optical transparency, an organic EL light emitting device on which such a layered color filter is mounted, and a fabrication method of such an organic EL light emitting device. The layered color filter includes a substrate 60, a red color filter 40R1, 40R2, a green color filter 40G1, 40G2, and a blue color filter 40B1, 40B2, 40B3 disposed on the substrate 60. In the layered color filter, the organic EL light emitting device on which such a layered color filter is mounted, and the fabrication method thereof, at least one color filter among the red color filter 40R1, 40R2, the green color filter 40G1, 40G2, and the blue color filter 40B1, 40B2, 40B3 is laminated to be formed as a plurality of thin film layers.

### CROSS REFERENCE TO RELATED APPLICATIONS AND INCORPORATION BY REFERENCE

This application is based upon and claims the benefit of priority from prior Japanese Patent Application Nos. P2012-122986 filed on May 30, 2012, P2012-128683 filed on Jun. 6, 2012, P2012-132136 filed on Jun. 11, 2012, and P2013-103909 filed on May 16, 2013, the entire contents of which are incorporated herein by reference.

### TECHNICAL FIELD

The present invention relates to an organic EL light emitting device, a fabrication method for the same, and a layered color filter.

### BACKGROUND ART

In recent years, display devices and lighting devices using organic electroluminescence (EL) elements as an organic light emitting element have been under development toward commercialization. Moreover, an organic electroluminescence display device is receiving attention as a next-generation thin display.

In such an organic electroluminescence display device, an upper electrode is disposed on an organic EL layer, and a color filter is disposed on the upper electrode (for example, refer to Patent Literature 1).

In this case, such a color filter is formed by coating a color resist on the upper electrode to being patterned with the lithography. The color resist is a light curing resin. A portion irradiated with ultraviolet light is cured and remains as a pattern (permanent resist). Generally, a pigment for absorbing light is dispersed in the light curing resin of such a color resist, in order that each color (red, green, and blue) is selectively passed therethrough.

In such an organic electroluminescence display device, since red, green, and blue pixels are provided adjoining to each other, color mixture (crosstalk) between the pixels becomes a problem.

There is disclosed a color conversion type organic electroluminescence display in which a crosstalk reduced structure is disposed between rows of organic EL devices, in order to reduce the color mixture (for example, refer to Patent Literature 2).

### CITATION LIST

Patent Literature 1: Japanese Patent Application Laying-Open Publication No. 2009-288435
Patent Literature 1: Japanese Patent Application Laying-Open Publication No. 2010-272214

### SUMMARY OF THE INVENTION

### Technical Problem

In order to improve the color selectivity due to the color resist, it is necessary to increase a resist thickness to increase a distance passed through by the light, or necessary to increase a degree of dispersion of such a pigment.

However, according to such methods, an optical transparency of ultraviolet light used for patterning the color resist is reduced, thereby reducing patterning characteristics. Accordingly, curing of the lower part of the resist becomes unsatisfactory.

Therefore, there had been occurred a defective condition of which an adhesibility between the color resist and a substrate is reduced due to a bottom surface thereof which has not been sufficiently cured. Moreover, if strong light is incident thereon in order to cure the resist compulsorily, there was a negative effect in which a transistor or a light emitting element which exists in the lower part of the resist is prone to degradation.

Moreover, as a film thickness of an organic EL layer in the sidewall part of the lower electrode becomes thinner, a short circuit can occur between the lower electrode and the upper electrode.

A purpose of the present invention is to provide a layered color filter which can improve optical selectivity, without reducing optical transparency, an organic EL light emitting device on which such a layered color filter is mounted, and a fabrication method of such an organic EL light emitting device.

Another purpose of the present invention is to provide an organic EL light emitting device in which a luminescent ability and a manufacturing yield can be improved, and a fabrication method of such an organic EL light emitting device.

Still another purpose of the present invention is to provide an organic EL light emitting device which can improve optical extraction efficiency while preventing a short circuit, and a fabrication method of such an organic EL light emitting device.

### Solution to Problem

According to an aspect of the present invention, there is provided an organic EL light emitting device comprising: in one pixel, a substrate; a driver circuit disposed on the substrate; a lower electrode disposed on the driver circuit; an organic EL layer disposed in common on the lower electrode; an upper electrode disposed on the organic EL layer; and a red color filter, a green color filter, and a blue color filter disposed on the upper electrode, wherein at least one color filter among the red color filter, the green color filter, and the blue color filter is formed as a plurality of thin film layers.

According to another aspect of the present invention, there is provided an organic EL light emitting device comprising: a substrate; a first VIA electrode disposed on the substrate; a lower electrode disposed on the first VIA electrode; an organic EL layer disposed in common on the lower electrode; an upper electrode disposed in common on the organic EL layer; and a second VIA electrode disposed on the substrate, the second VIA electrode directly contacted to the upper electrode.

According to still another aspect of the present invention, there is provided an organic EL light emitting device comprising:

a substrate; a first VIA electrode disposed on the substrate; a lower electrode disposed on the first VIA electrode, the lower electrode having a metallic oxide film on a surface thereof; an organic EL layer disposed in common on the lower electrode; an upper electrode disposed in common on the organic EL layer; and a second VIA electrode disposed on the substrate.

According to still another aspect of the present invention, there is provided an organic EL light emitting device comprising:

a substrate; an adhesive layer disposed on the substrate; a lower electrode disposed on the adhesive layer; an organic EL layer disposed in common on the lower electrode; and an upper electrode disposed on the organic EL layer, wherein a sidewall part of the adhesive layer and a sidewall part of the lower electrode have a tapered shape.

According to still another aspect of the present invention, there is provided an organic EL light emitting device comprising:

a substrate; an adhesive layer disposed on the substrate; a lower electrode disposed on the adhesive layer; an organic EL layer disposed in common on the lower electrode; an upper electrode disposed on the organic EL layer; and an insulating film disposed between a sidewall part of the lower electrode and the organic EL layer.

According to still another aspect of the present invention, there is provided an organic EL light emitting device comprising:

a substrate; an adhesive layer disposed on the substrate; a lower electrode disposed on the adhesive layer; an organic EL layer disposed in common on the lower electrode; and an upper electrode disposed on the organic EL layer, wherein a constant height of the organic EL layer is formed on a whole region of a top surface part of the lower electrodes and between the lower electrodes.

According to still another aspect of the present invention, there is provided an organic EL light emitting device comprising: a substrate; an adhesive layer disposed on the substrate; a lower electrode disposed on the adhesive layer; an organic EL layer disposed in common on the lower electrode; and an upper electrode disposed on the organic EL layer, wherein the upper electrode is formed only on a region facing a top surface part of the lower electrode.

According to still another aspect of the present invention, there is provided a fabrication method of an organic EL light emitting device, the organic EL light emitting device comprising, in one pixel, a substrate, a driver circuit disposed on the substrate, a lower electrode disposed on the driver circuit, an organic EL layer disposed in common on the lower electrode, an upper electrode disposed on the organic EL layer, and a red color filter, a green color filter, and a blue color filter disposed on the upper electrode, the fabrication method comprising: applying a color resist to be exposes and developed; and applying a color resist of the same color thereon again to be exposed and developed, wherein at least one color filter among the red color filter, the green color filter, and the blue color filter is formed as a plurality of thin film layers.

According to still another aspect of the present invention, there is provided a fabrication method of an organic EL light emitting device, the organic EL light emitting device comprising a substrate, a first VIA electrode disposed on the substrate, a lower electrode disposed on the first VIA electrode, an organic EL layer disposed in common on the lower electrode, an upper electrode disposed in common on the organic EL layer, and a second VIA electrode disposed on the substrate, the second VIA electrode directly contacted to the upper electrode, the fabrication method comprising: forming a dummy lower electrode with the lower electrode on the substrate; removing the dummy lower electrode; forming the organic EL layer on the lower electrode; and forming the upper electrode on the organic EL layer so as to be directly contacted to the second VIA electrode.

According to still another aspect of the present invention, there is provided a fabrication method of an organic EL light emitting device, the fabrication method comprising: preparing a substrate; forming a lower electrode on the substrate; processing a surface of the substrate; forming an organic EL layer on the lower electrode; and forming an upper electrode on the organic EL layer.

According to still another aspect of the present invention, there is provided a fabrication method of an organic EL light emitting device, the fabrication method comprising: preparing a substrate; forming an adhesive layer on the substrate; forming a lower electrode on the adhesive layer; forming a sidewall part of the adhesive layer and a sidewall part of the lower electrode in a tapered shape; forming an organic EL layer on the lower electrode; and forming an upper electrode on the organic EL layer.

According to still another aspect of the present invention, there is provided a fabrication method of an organic EL light emitting device, the fabrication method comprising: preparing a substrate; forming a trenching on the substrate; forming an adhesive layer in the trench; filling up the trench and forming a lower electrode on the adhesive layer; performing polishing process of the adhesive layer and the lower electrode so that a height position of a top surface part of the substrate is aligned with the same height position as a top surface part of the lower electrode; forming an organic EL layer on the lower electrode; and forming an upper electrode on the organic EL layer.

According to still another aspect of the present invention, there is provided a layered color filter comprising: a substrate; a red color filter disposed on the substrate; a green color filter disposed on the substrate; and a blue color filter disposed on the substrate, wherein at least one color filter among the red color filter, the green color filter, and the blue color filter is formed as a plurality of thin film layers.

### Advantageous Effects of Invention

According to the present invention, there can be provided a layered color filter which can improve optical selectivity, without reducing optical transparency, an organic EL light emitting device on which such a layered color filter is mounted, and a fabrication method of such an organic EL light emitting device.

Moreover, according to the present invention, there can be provided an organic EL light emitting device in which a luminescent ability and a manufacturing yield can be improved, and a fabrication method of such an organic EL light emitting device.

Furthermore, according to the present invention, there can be provided an organic EL light emitting device which can improve optical extraction efficiency while preventing a short circuit, and a fabrication method of such an organic EL light emitting device.

### BRIEF DESCRIPTION OF DRAWINGS

FIG. 1 is a schematic cross-sectional structure diagram showing one pixel part of an organic EL light emitting device according to a fundamental structure.

FIG. 2 is a schematic bird's-eye view showing one pixel part of the organic EL light emitting device according to the fundamental structure.

FIG. 3 is a cross-sectional SEM photograph of the organic EL light emitting device according to the fundamental structure.

FIG. 4 is a diagram showing an example of a schematic block configuration including a peripheral circuitry of the organic EL light emitting device according to the fundamental structure.

FIG. 5 is a schematic cross-sectional structure diagram showing a color filter according to a comparative example 1.

FIG. 6 is a schematic cross-sectional structure diagram showing a layered color filter according to a first embodiment.

FIG. 7 is a schematic planar pattern configuration diagram for explaining an overlap effect of the layered color filter according to the first embodiment.

FIG. 8 is a schematic cross-sectional configuration diagram taken in the line I-I of FIG. 7.

FIG. 9 is a schematic diagram showing a relationship of coefficients of optical absorption and wavelengths of a red color filter, a green color filter, and a blue color filter, in the layered color filter according to the first embodiment.

FIG. 10 is a schematic plane constitution diagram of the layered color filter according to the first embodiment having an example of a delta arrangement pattern on the basis of a hexagon.

FIG. 11 is a schematic cross-sectional structure diagram of a layered color filter according to a modified example 1 of the first embodiment.

FIG. 12 is a schematic cross-sectional structure diagram of a layered color filter according to a modified example 2 of the first embodiment.

FIG. 13 is a schematic cross-sectional structure diagram of a layered color filter according to a modified example 3 of the first embodiment.

FIG. 14 is a schematic cross-sectional structure diagram of a layered color filter according to a modified example 4 of the first embodiment.

FIG. 15 is a schematic cross-sectional structure diagram of a layered color filter according to a modified example 5 of the first embodiment.

FIG. 16 is a schematic cross-sectional structure diagram of a layered color filter according to a modified example 6 of the first embodiment.

FIG. 17 is a schematic cross-sectional structure diagram showing one pixel part of an organic EL light emitting device on which the layered color filter according to the first embodiment is mounted.

FIG. 18 is a bird's-eye view surface SEM photograph example of the organic EL light emitting device on which the layered color filter according to the first embodiment is mounted.

FIG. 19 is a cross-sectional SEM photograph example of the organic EL light emitting device on which the layered color filter according to the first embodiment is mounted.

FIG. 20 is an enlarged cross-sectional SEM photograph of the layered color filter part shown in FIG. 19.

FIG. 21 is a detailed explanatory diagram of the layered color filter part shown in FIG. 20.

FIG. 22 is a configuration diagram of a planar layout pattern showing a pixel array and a perimeter thereof of an organic EL light emitting device according to a comparative example 3 and second to fifth embodiments.

FIG. 23 is a schematic cross-sectional structure diagram taken in the line II-II of FIG. 22, in the organic EL light emitting device according to the comparative example 3.

FIG. 24 is a schematic cross-sectional structure diagram taken in the line II-II of FIG. 22, in the organic EL light emitting device according to the second embodiment.

FIG. 25 is a schematic cross-sectional structure diagram taken in the line II-II of FIG. 22, in the organic EL light emitting device according to the third embodiment (Phase 1).

FIG. 26A is a schematic cross-sectional structure diagram taken in the line II-II of FIG. 22, in the organic EL light emitting device according to the third embodiment (Phase 2).

FIG. 26B is a schematic enlarged configuration diagram showing a part P shown in FIG. 26A.

FIG. 27 is a graphic chart showing a leakage current between lower electrodes of the organic EL light emitting device according to the third embodiment, and a leakage current between lower electrodes of the organic EL light emitting device according to the comparative example 3.

FIG. 28 is a schematic cross-sectional structure diagram for explaining a leakage current between the lower electrodes and an applied cathode voltage of the organic EL light emitting device according to the third embodiment.

FIG. 29 is a schematic cross-sectional structure diagram for explaining a fabrication method of the organic EL light emitting device according to the comparative example 3.

FIG. 30A is a schematic cross-sectional structure diagram for explaining a fabrication method of the organic EL light emitting device according to the fourth embodiment.

FIG. 30B is a schematic planar structure diagram of an Si wafer for explaining the fabrication method of the organic EL light emitting device according to the fourth embodiment.

FIG. 31A is a schematic cross-sectional structure diagram for explaining the fabrication method of the organic EL light emitting device according to the comparative example 3.

FIG. 31B is a schematic enlarged configuration diagram showing a part Q shown in FIG. 31A.

FIG. 32A is a schematic cross-sectional structure diagram for explaining a fabrication method of the organic EL light emitting device according to the fifth embodiment.

FIG. 32B is a schematic enlarged configuration diagram of a part R shown in FIG. 32A.

FIG. 33 is a graphic chart showing a leakage current between lower electrodes of the organic EL light emitting device according to the fifth embodiment, and a leakage current between lower electrodes of the organic EL light emitting device according to the comparative example 3.

FIG. 34 is a schematic plane constitution diagram of a layered color filter mounted on the organic EL light emitting device according to the fifth embodiment, the layered color filter having an example of a delta arrangement pattern on the basis of hexagon.

FIG. 35 is a schematic cross-sectional structure diagram taken in the line III-III line of FIG. 34, in the organic EL light emitting device according to the fifth embodiment.

FIG. 36A is a schematic cross-sectional structure diagram showing an organic EL light emitting device according to a comparative example 2, and showing a state before metal processing using dry etching.

FIG. 36B is a schematic cross-sectional structure diagram showing the organic EL light emitting device according to the comparative example 2, and showing a state after the metal processing using the dry etching.

FIG. 36C is a schematic cross-sectional structure diagram showing the organic EL light emitting device according to the comparative example 2, and showing a state where an upper electrode is disposed on an organic EL layer.

FIG. 37 is a schematic cross-sectional structure diagram for explaining optical extraction efficiency in the organic EL light emitting device according to the comparative example 2.

FIG. 38 is a schematic cross-sectional structure diagram of an organic EL light emitting device according to a sixth embodiment.

FIG. 39 is a schematic cross-sectional structure diagram showing RB sub-pixel parts adjoining to each other, in the organic EL light emitting device according to the sixth embodiment.

FIG. 40 is a schematic cross-sectional structure diagram of an organic EL light emitting device according to a seventh embodiment.

FIG. 41 is a schematic cross-sectional structure diagram showing RB sub-pixel parts adjoining to each other, in the organic EL light emitting device according to the seventh embodiment.

FIG. 42 is a schematic cross-sectional structure diagram showing RB sub-pixel parts adjoining to each other, in an organic EL light emitting device according to a modified example 1 of the seventh embodiment.

FIG. 43 is a schematic cross-sectional structure diagram showing RB sub-pixel parts adjoining to each other, in an organic EL light emitting device according to a modified example 2 of the seventh embodiment.

FIG. 44 is a schematic cross-sectional structure diagram showing RB sub-pixel parts adjoining to each other, in an organic EL light emitting device according to a modified example 3 of the seventh embodiment.

FIG. 45A is a schematic cross-sectional structure diagram of one pixel part in the organic EL light emitting device according to the seventh embodiment.

FIG. 45B is a schematic enlarged configuration diagram of a part P shown in FIG. 45A.

FIG. 46 is a schematic cross-sectional structure diagram of an organic EL light emitting device according to a eighth embodiment.

FIG. 47 is a schematic cross-sectional structure diagram of an organic EL light emitting device according to a ninth embodiment.

FIG. 48 is a schematic cross-sectional structure diagram of an organic EL light emitting device according to a tenth embodiment.

FIG. 49 is a schematic cross-sectional structure diagram showing an organic EL light emitting device according to a modified example of the tenth embodiment.

FIG. 50 is a schematic cross-sectional structure diagram of an organic EL light emitting device according to a eleventh embodiment.

FIG. 51 is a schematic cross-sectional structure diagram of an organic EL light emitting device according to a twelfth embodiment.

### DESCRIPTION OF EMBODIMENTS

Next, embodiments of the invention will be described with reference to drawings. In the description of the following drawings, the identical or similar reference numeral is attached to the identical or similar part. However, it should be known about that the drawings are schematic and the relation between thickness and the plane size of each component part and the ratio of the thickness of each layer differs from an actual thing. Therefore, detailed thickness and size should be determined in consideration of the following explanation. Of course, the part from which the relation and ratio of a mutual size differ also in mutually drawings is included.

Moreover, the embodiments shown hereinafter exemplify the apparatus and method for materializing the technical idea of the present invention; and the embodiments of the present invention does not specify the material, shape, structure, placement, etc. of each component part as the following. Various changes can be added to the technical idea of the present invention in scope of claims.

In organic EL light emitting device(s) according to the following embodiments, “transparent” is defined as that whose transmissivity is not less than about 50%. In the organic EL light emitting device(s) according to the embodiments, the “transparent” is used for the purpose of being transparent and colorless with respect to visible light. The visible light is equivalent to light having a wavelength of approximately 360 nm to approximately 830 nm and energy of approximately 3.4 eV to approximately 1.5 eV, and it can be said that it is transparent if the transmission rate is not less than 50% in such a region.

### [Fundamental Structure of Organic EL Light Emitting Device]

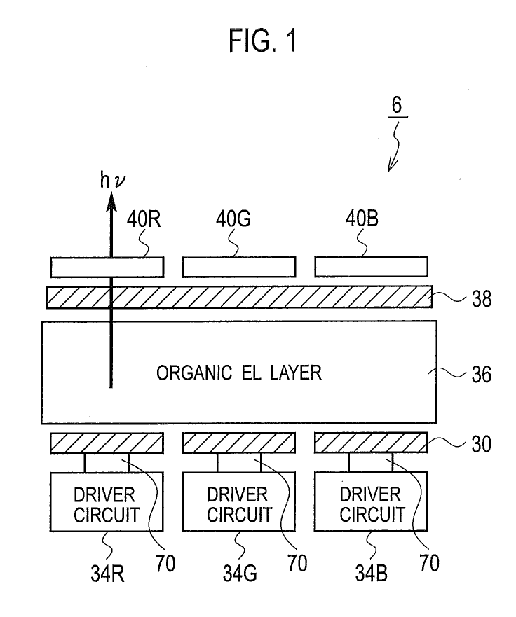

As shown in FIG. 1, a schematic cross-sectional structure of one pixel part of an organic EL light emitting device according to a fundamental structure includes: driver circuits 34R, 34G, 34B; a VIA electrode (anode VIA electrode) 70 respectively disposed on each driver circuit 34R, 34G, 34B; a lower electrode 30 disposed on each VIA electrode (anode VIA electrode) 70; an organic EL layer 36 disposed as a common region on the lower electrode 30; an upper electrode 38 disposed on the organic EL layer 36; and color filters 40R, 40G, 40B disposed on the upper electrode 38.

The driver circuits 34R, 34G, 34B are respectively shown as driver circuits 34 for red, green, and blue.

Similarly, the color filters 40R, 40G, 40B are respectively shown as color filters 40 for red, green, and blue.

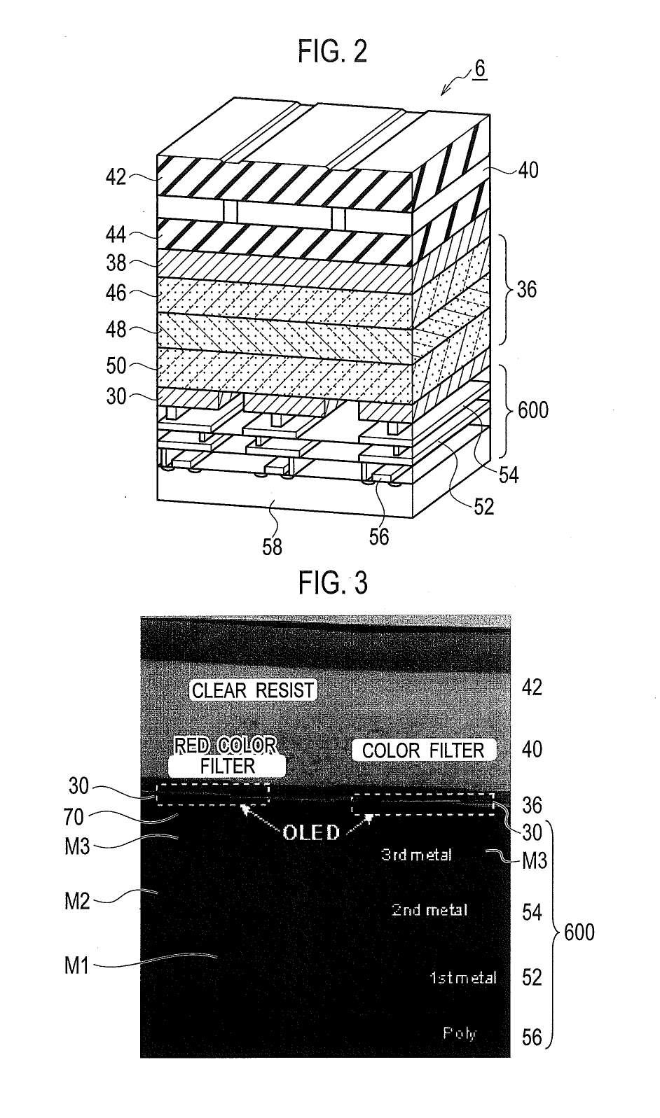

More specifically, as shown in FIG. 2, the driver circuits 34R, 34G, 34B, and the VIA electrode (anode VIA electrode) 70 disposed respectively on each driver circuits 34R, 34G, 34B compose a complementary type (C) MOSLSI 600 disposed on the semiconductor substrate 58. Agate electrode 56 of the CMOSFET, an M1 electrode 52 and an M2 electrode 54 which further form an electrode wiring layer, etc. (omitted for details in FIG. 2) are connected through an interlayer insulating film and the VIA electrode.

As shown in FIG. 2, the organic EL layer 36 includes: a hole transport layer 50 sandwiched between the lower electrode 30 and the upper electrode 38, the hole transport layer 50 disposed on the lower electrode 30; a light-emitting layer 48 disposed on the hole transport layer 50; and an electron transport layer 46 disposed on the light-emitting layer 48.

Furthermore, as shown in FIG. 2, the organic EL light emitting device according to the basic configuration includes: an upper electrode 38 disposed on the electron transport layer 46; a sealing layer 44 disposed on the upper electrode 38; a color filter 40 disposed on the sealing layer 44; and a transparent protective film 42 disposed on the color filter 40.

FIGS. 1 and 2 correspond to one pixel 6, and a structure of such a pixel 6 is disposed, for example, at matrix shape, in the organic EL light emitting device.

In an example shown in FIGS. 1 and 2, the upper electrode 38 is formed as a common electrode, and each lower electrode 30 is composed as a divided electrode. On the contrary, the upper electrode 38 may be formed as divided electrodes, and the lower electrode 30 may be composed as a common electrode. In this case, each VIA electrode (anode VIA electrode) 70 is respectively connected to each upper electrode 38 formed as a divided electrode. Furthermore, in the structure shown in FIG. 1, the upper electrode 38 may also be formed as divided electrodes.

Moreover, although FIG. 2 shows an example in which the hole transport layer 50 is disposed as a layer which contacts the lower electrode 30, and the electron transport layer 46 is disposed as a layer which contacts the upper electrode 38, it is not limited to the above-mentioned example. The electron transport layer 46 may be disposed as a layer which contacts the lower electrode 30, and the hole transport layer 50 may be disposed as a layer which contacts the upper electrode 38. However, in this case, electric wiring from the CMOSLSI 600 will be changed. Moreover, the above-mentioned upper electrode 38 may be formed as divided electrodes, and may be combined with a structure in which the lower electrode 30 is formed as a common electrode.

FIG. 3 shows an example of a cross-sectional SEM photograph of the organic EL light emitting device according to the basic configuration.

As the organic EL light emitting device according to the basic configuration is shown in FIG. 3, the organic EL layer 36 is laminated via the lower electrode 30 on the CMOSLSI 600.

In addition, although FIG. 2 shows a structure of two-layered metal including the M1 electrode 52 and the M2 electrode 54, it is not limited to the above-mentioned structure. As shown in FIG. 3, the metal layer may be three-layered metal. The number of layers of the metal may be appropriately selected depending on a wiring scale.

FIGS. 1 and 2 show a structure of one pixel disposed on an intersection part between a plurality of data lines and a plurality of scanning lines, the CMOSLSI 600 composed of the CMOSFET formed on the semiconductor substrate 58 composes a logic circuit, and composes driver circuits 34R, 34G, 34B in one pixel.

Moreover, in the organic EL light emitting device according to the basic configuration, the CMOSLSI 600 composes a horizontal scanning circuit, a vertical scanning circuit, a row driver, a column driver, a data latch circuit, a PNM driver, etc. used for driving the pixel array.

In the structure shown in FIGS. 1 and 2, formation of the M1 electrode 52 and M2 electrode 54 via the CMOSFET region and each interlayer insulating film, etc. is the same as that of miniaturization silicon processing.

Between the electrodes (e.g., the M1 electrode 52 and the M2 electrode 54) is connected to each other with a metal damascene structure via a VIA electrode in a predetermined contact portion.

The transparent protective film 42 can be formed of a clear resist, a glass, a transparent insulating film, etc., for example.

The color filter 40 is disposed on the sealing layer 44, in order to display a color image in a visible light wavelength region. The color filters for red, green, and blue are respectively disposed on one pixel adjoining to each other, thereby composing one pixel using a set of three color filters (red, green, and blue). The color filter can be formed of multilayered film of a glass, or multilayering of a gelatin film, for example. Alternatively, the color filter can be formed of a multilayered film on a glass, or multilayering of a dyes/pigment-containing resist, for example.

The sealing layer 44 seals to protect the upper electrode 38, the organic EL layer 36, and the organic EL lower electrode 30. As materials of the sealing layer 44, a silicon oxide film, a silicon nitride film, or an alumina film may be used. Moreover, since the sealing layer 44 acts as a function which dissipates heat to outside, it is preferable to use a sealing layer with higher coefficient of thermal conductivity.

The upper electrode 38 allows the light to pass through, and can be formed of inorganic conductive materials, e.g. indium tin oxide (ITO) and indium zinc oxide (IZO). Moreover, the upper electrode 38 can also be formed of a thin-layered layer (e.g., approximately 10 nm to approximately 20 nm) of a metal (e.g., Al, Ag, MgAg, etc.).

The electron transport layer 46 transports smoothly electrons injected from the upper electrode 38 to the light-emitting layer 48, and is composed of Alg₃ (aluminum quinolinol complex) with approximately 35 nm-thick, for example. Herein, Alg₃ is a material called Aluminum 8-hydroxyquinolinate or Tris(8-quinolinolato)aluminum.

As other electron transport materials for forming the electron transport layer 46, there are t-butyl-PBD, TAZ, a silole derivative, a boron replacement type triaryl based compound, a phenylquinoxaline derivative, etc. Moreover, BCP, an oxadiazole dimer, a starburst oxadiazole, etc. are also applicable as the electron transport materials.

The light-emitting layer 48 is a layer for emitting light by having the injected holes and electrons recombined therein, and is formed of Alq3 doped with a coumarin compound (C545T) being a light-emitting species at a concentration of approximately 1%, with a thickness of approximately 30 nm, for example. Moreover, a complex including rubrene and a transition metal atom may be included as the dopant.

A carrier transport light-emitting material, or a compound layer of a light-emitting dopant and a host material, for example, can also be applicable to the light-emitting layer 48. As a carrier transport light-emitting material, there can be used materials, e.g., Alq, Almq, Mgq, BeBq₂, ZnPBO, ZnPBT, Be(5Fla)₂. an Eu complex, BPVBi, BAlq, Bepp₂, BDPHVBi, spiro-BDPVBi, (PSA)₂Np-5, (PPA) (PSA)Pe-1, BSN, APD, BSB, etc. for example. As a light-emitting dopant and host materials, there can be used materials, e.g., coumarin 6, C₅₄₅T, Qd4, DEQ, perylene, DPT, DCM2, DCJTB, rubrene, DPP, CBP, ABTX, DSA, DSA amine, Co-6, PMDFB, Quinacridone, BTX, DCM, DCJT, etc. for example. Moreover, as phosphorescence-emitting materials, a host, and perimeter material, there can be used materials, e.g. PtOEP, TPBI, btp₂Ir (acac), Ir(ppy)₃, Flrpic, CDBP, m-CP, dendrimer Ir(ppy)₃, TCTA, CF-X, CF-Y, etc.

The hole transport layer 50 is a layer for smoothly transport holes injected from the organic EL lower electrode 30 to the light-emitting layer 48, and is composed of NPB (N,N-di(naphthyl)-N,N-diphenyl-benzidene) with approximately 60-nm thickness, for example. As other hole transport layers, α-NPD can be used, for example. Herein, α-NPD is called (4,4-bis[N-(1-naphtyl-1-)N-phenyl-amino]-biphenyl).

As an example of molecular structure of the hole transport material for forming the hole transport layer 50, there are applicable GPD, spiro-TAD, spiro-NPD, and oxidized-TPD. Furthermore, there are TDAPB, MTDATA, etc. as another hole transport material.

The thickness of the lower electrode 30 is approximately 150 nm, for example, and a material of the lower electrode 30 is aluminum. As other composite materials, there are applicable Mo, Ag, Pt, etc.

In addition, the light-emitting layer 48 may be composed using layers (e.g., a hole injection layer, an electron injection layer, etc.), except the above-mentioned hole transport layer and electron transport layer.

The operational principle of the organic EL light emitting device according to the basic configuration is as follows.

First, a certain voltage is applied between the hole transport layer 50 and the electron transport layer 46 of the organic EL layer 36 through the lower electrode 30 and the upper electrode 38. Accordingly, holes are injected into the hole transport layer 50 light-emitting layer 48, electrons are injected into the light-emitting layer 48 from the electron transport layer 46. Then, the holes and electrons injected into the light-emitting layer 48 are recombined with each other, thereby emitting white light. The emitted white light by passes through the upper electrode 38, and is output to the outside through the color filter 40.

It is effective for the absolute value of the energy level of highest occupied molecular orbital (HOMO) of the hole transport layer 50 which composes the organic EL layer 36 to be set up larger than the absolute value of the work function of the organic EL lower electrode.

Herein, the HOMO energy level expresses a ground state of an organic molecule. Moreover, the energy level of lowest unoccupied molecular orbital (LUMO) expresses an excited state of the organic molecule.

Herein, the LUMO energy level corresponds to a lowest excited singlet level (S1). As for the level of holes and electrons in the case where electrons and holes are further implanted into an organic matter and a radical anion (M−) and radical cation (M+) are formed, an electron conduction level and a hole conduction level is located at the position of the outside of the HOMO level and the LUMO energy level corresponding to the worth in which exciton binding energy does not exist.

Moreover, the absolute value of the LUMO energy level of the electron transport layer 46 may be smaller than the absolute value of the work function of the upper electrode 38.

In the structure of the organic EL light emitting device according to the basic configuration, each electrode and each layer are respectively formed by sputtering, vacuum evaporation, coating, etc.

In the structure of the organic EL light emitting device according to the basic configuration, a p type organic semiconductor layer may be inserted between the light-emitting layer 48 and the hole transport layer 50 or between the organic EL lower electrode 30 and the hole transport layer 50. Similarly, an n type organic semiconductor layer may be inserted between the light-emitting layer 48 and the electron transport layer 46 or between the upper electrode 38 and the electron transport layer 46.

### (Block Configuration of Organic EL Light Emitting Device)

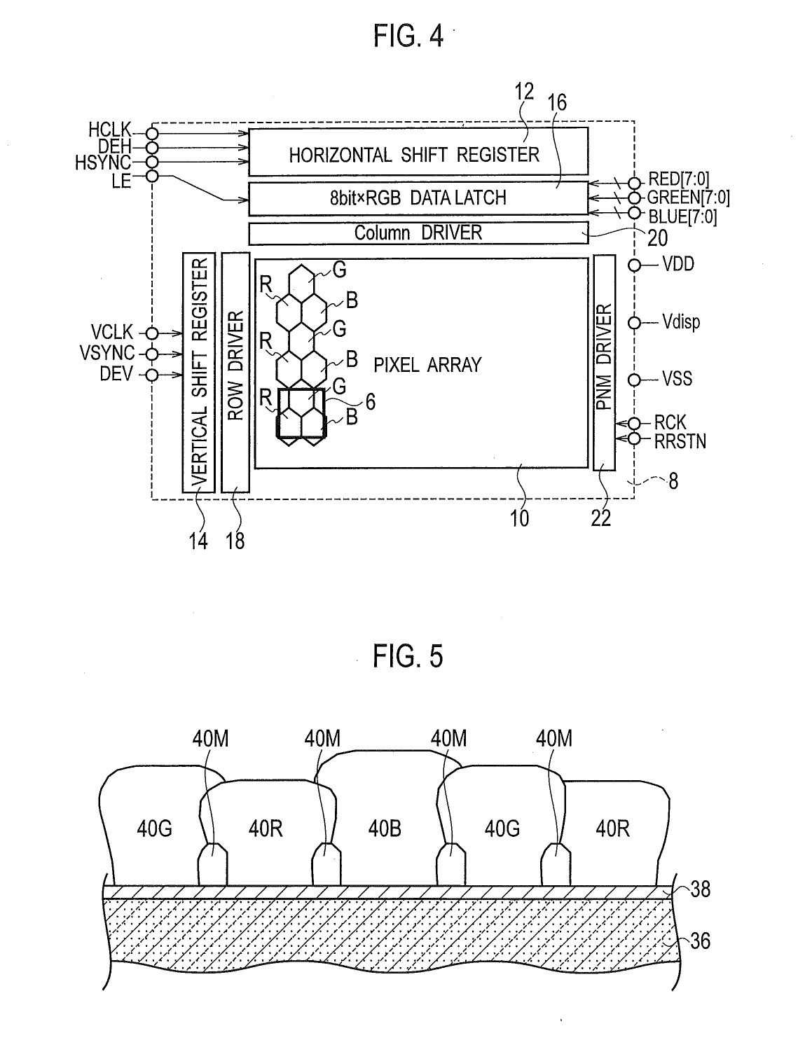

As shown in FIG. 4, a schematic block configuration example including a peripheral circuitry of the organic EL light emitting device 8 according to the basic configuration includes: a pixel array 10; a column driver 20 disposed adjoining in a column direction of the pixel array 10; a data latch circuit 16 disposed adjoining in a column direction of the column drivers 20; a horizontal shift register (H shift register) 12 disposed adjoining in a column direction of the data latch circuit 16; a row driver 18 disposed adjoining in a row direction of the pixel array 10; a vertical shift register (V shift register) 14 disposed adjoining to the row driver 18; and a PNM driver 22 disposed adjoining in a row direction of the pixel array 10.

Data lines D0, D1, D2, D3 used for driving pixels 6 in the pixel array 10 are connected to the column drivers 20.

The data latch circuit 16 is a circuit for latching 4-bit video image data signals RED [3:0], GREEN [3:0], and BLUE [3:0], in the example shown in FIG. 4. Moreover, the data latch circuit 16 is activated when inputting a latch enable signal LE as an external signal.

The horizontal shift register 12 is a circuit for horizontal scanning the pixel array 10, and receiving a pixel clock signal HCLK, a shift/hold switching signal DEH, and a horizontal synchronization reset signal HSYNC.

Scanning lines K0, K1, K2, K3, . . . , and a word line WL for driving the pixel 6 in the pixel array 10 are connected to the row driver 18.

The vertical shift register 14 is a circuit for vertical scanning the pixel array 10, and receiving a clock signal VCK, a shift/hold switching signal DEV, and a vertical synchronization reset signal VSYNC.

PNM driver 22 transmits a PNM signals PNMO, PNM1, PNM2, PNM3, . . . to the scanning lines K0, K1, K2, K3, A PNM clock signal RCK and a PNM reset signal RRSTN are input into the PNM driver 22.

Moreover, for example, a display power source Vdisp of approximately −5V and a system power source VDD of approximately 3.3V are supplied to the organic EL light emitting device 8 according to the basic configuration, and a common ground potential of Vss is also given to the organic EL light emitting device 8.

Each sub pixel in the pixel array 10 in FIG. 4 has a structure in which hexagon is used as a basic pattern. Note that the shape of each sub pixel may be not only the hexagon, but also polygons, e.g. a circular form, a triangle, a square, an octagon, etc.

### Comparative Example 1

In a color filter of a comparative example 1, as shown in FIG. 5, relatively thick red color resist 40R, green color resist 40G, blue color resist 40B are respectively formed as one layer on the upper electrode 38 disposed on the organic EL layer 36. Moreover, black color resists 40M are disposed on each adjoining part of the red color resist 40R, the green color resist 40G, and the blue color resist 40B. By forming the black color resists 40M, a black matrix for preventing color mixture is formed.

### Comparative Example 2

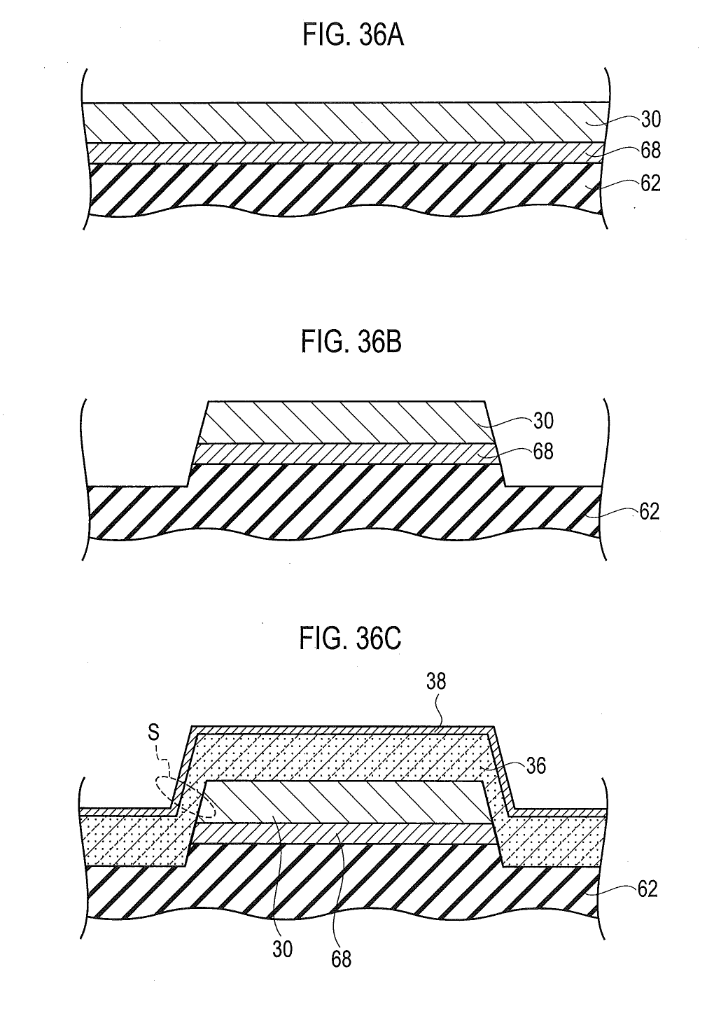

FIG. 36A shows a schematic cross-sectional structure of an organic EL light emitting device according to a comparative example 2 in a state before metal processing using dry etching. FIG. 36B shows a state after the metal processing using the dry etching, and FIG. 36C shows a state where an upper electrode is disposed on an organic EL layer.

As shown in FIG. 36, a cross-sectional shape of a sidewall part of the organic EL light emitting device according to the comparative example 2 is formed in a shape close to almost vertical. More specifically, as shown in FIG. 36A, a metal layer which is a material of an adhesive layer 68 is laminated on an insulating layer 62, and a metal layer which is a material of a lower electrode 30 is further laminated on the adhesive layer 68. The adhesive layer 68 and the lower electrode 30 are formed by patterning using lithography in this state, and processing the metal layer using dry etching, as shown in FIG. 36B. The cross-sectional shape of a sidewall part of the adhesive layer 68 and a sidewall part of the lower electrode 30 is a shape close to almost vertical. Furthermore, as shown in FIG. 36C, an organic EL layer 36 is disposed on the lower electrode 30, and an upper electrode 38 is disposed on the organic EL layer 36.

In the organic EL light emitting device according to the comparative example 2, the film thickness of the organic EL layer 36 in the sidewall part of the lower electrode 30 becomes extremely thinner. Accordingly, a short circuit may occur in a sidewall part S between the lower electrode 30 and the upper electrode 38.

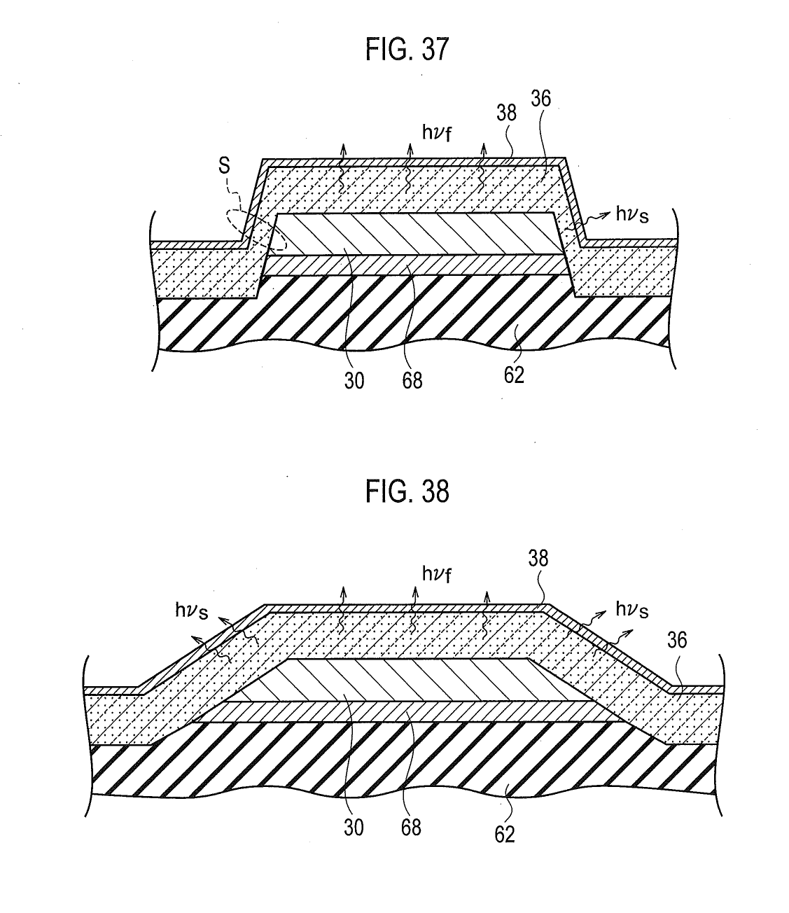

Moreover, FIG. 37 shows a schematic cross-sectional structure for explaining optical extraction efficiency in the organic EL light emitting device according to the comparative example 2. In this comparative example 2, brightness intensity of light hυₛ emitted from the sidewall part is higher than that of light hυ_{f} emitted from a top surface part (main part) of the lower electrode 30.

In the organic EL light emitting device according to the comparative example 2, since the film thickness of the organic EL layer 36 at the sidewall part is thinner than that at the top surface part (main part) of the lower electrode 30, an electric field is easier to be concentrated on the organic EL layer 36 at the sidewall part. Accordingly, a voltage which can be applied between the sidewall part and the upper electrode 38 becomes lower than a voltage which can be applied between the top surface part and the upper electrode 38. Accordingly, when a voltage is applied to the upper electrode 38, the brightness intensity of the light hυ_{f} emitted from the top surface part (main part) is relatively reduced compared with the brightness intensity of the light hυₛ emitted from the sidewall part.

### First Embodiment

The same reference numeral is attached for the similar configuration as the organic EL light emitting device according to the basic configuration, and detailed explanation will be omitted. Note that the same reference numeral is used in particular in the following explanation, without distinguishing color resist and the color filter.

### (Layered Color Filter)

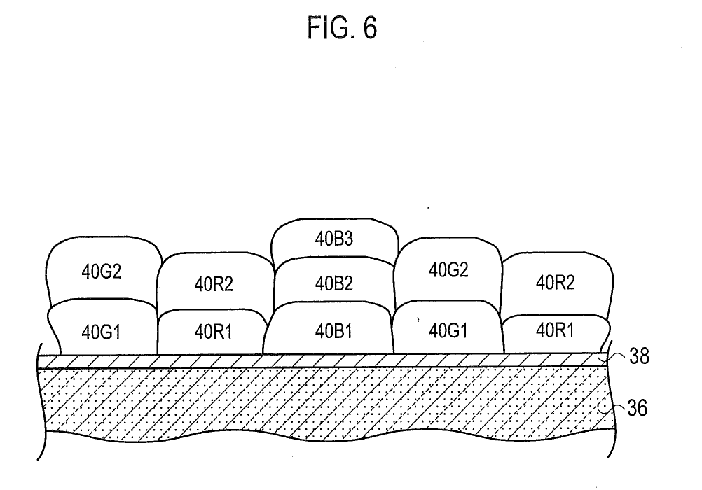

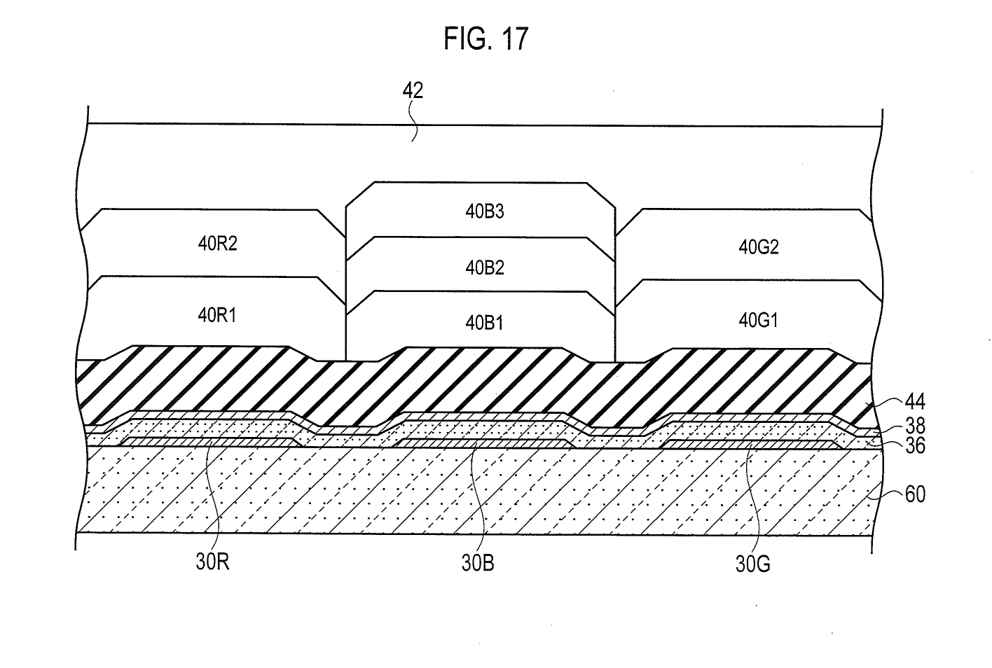

As shown in FIG. 6, a layered color filter according to a first embodiment includes: a substrate having an organic EL layer 36 and an upper electrode 38 on a surface thereof; red color filters 40R (40R1, 40R2) disposed on the substrate; green color filters 40G (40G1, 40G2) disposed on the substrate; and blue color filters 40B (40B1, 40B2, 40B3) disposed on the substrate. In this case, at least one color filter among the red color filter 40R, the green color filter 40G, and the blue color filter 40B is laminated to be formed as a plurality of thin film layers. Moreover, the substrate can be formed with a semiconductor wafer 60 (refer to FIG. 17) etc. Moreover, the substrate may be a glass substrate. A flexible substrate, such as a gas barrier plastic film, can also be used for the substrate. Note that although the color resists 40G, 40R, 40B are formed on the upper electrode 36 in FIG. 6, the color resists 40G, 40R, 40B may be formed on a sealing layer 44 disposed on the upper electrode 36 as shown in FIG. 17 described later.

Moreover, as shown in FIG. 6, the blue color filters 40B may be formed so that the number of layers of the blue color filters 40B is larger than the number of layers of the red color filters 40R or the green color filters 40G.

Moreover, the red color filters 40R (40R1, 40R2) may be formed in two layers, the green color filters 40G (40G1, 40G2) may be formed in two layers, and the blue color filters 40B (40B1, 40B2, 40B3) may be formed in three layers.

In this case, the film thickness of each layer of the red color filters 40R1, 40R2, the green color filters 40G1, 40G2, and the blue color filters 40B1, 40B2, 40B3 is equal to or less than approximately 1 micron, for example.

Moreover, the film thickness of the blue color filters 40B (40B1+40B2+40B3) may be thinner than the film thickness of the red color filters 40R (40R1+40R2) or the green color filters 40G (40G1+40G2).

Moreover, a resist pattern dimension of the red color filters 40R1, 40R2, the green color filters 40G1, 40G2, and the blue color filters 40B1, 40B2, 40B3 is equal to or less than approximately 10 microns in a planar view.

In addition, in a micro display, the width of the sub pixel on which the color filters 40B, 40G, 40R are mounted is approximately 1 pm to approximately 20 pm, for example, and the thickness on which the second electrode 38 and the color filters 40B, 40G, 40R overlapped one another is approximately 1 pm to approximately 100 pm, for example.

(Overlap effect of Color Filter)

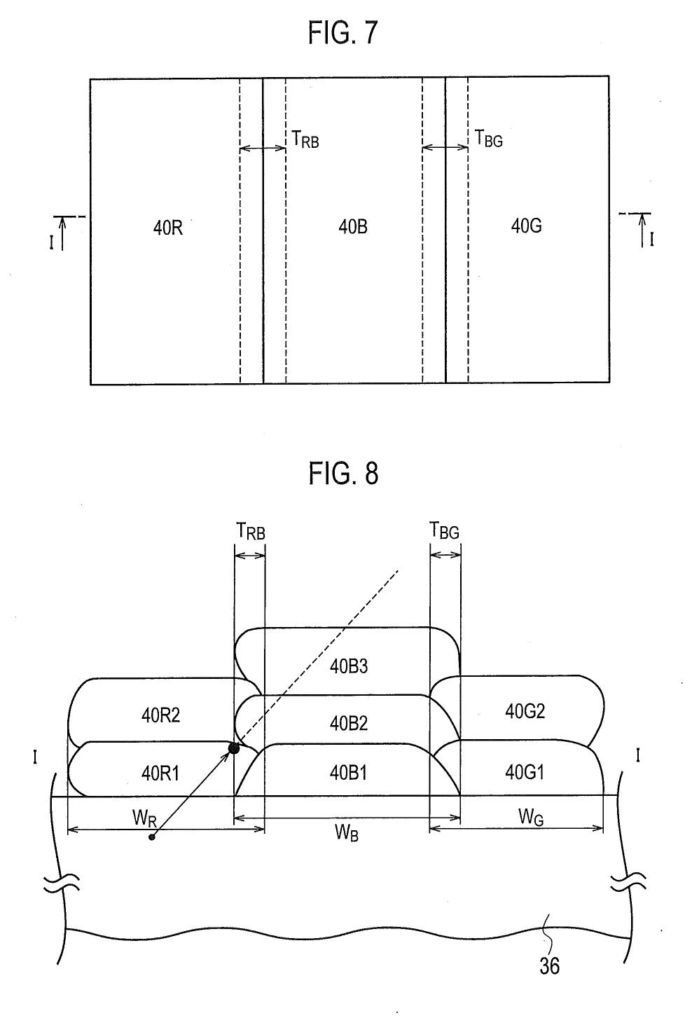

FIG. 7 shows a schematic planar pattern configuration for explaining an overlap effect of the layered color filter according to the first embodiment. FIG. 8 shows a schematic cross-sectional configuration taken in the line I-I of FIG. 7. FIG. 7 shows an example of overlapping the red color filter 40R (40R1, 40R2), the blue color filter 40B (40B1, 40B2, 40B3), and the green color filter 40G (40G1, 40G2) one another to be disposed on a sub pixel, with respect to rectangular-shaped one pixel.

As shown in FIG. 7 and FIG. 8, the layered color filter according to the first embodiment, the color filters adjoining to each other among the red color filter 40R1, 40R2, the green color filter 40G1, 40G2, and the blue color filter 40B1, 40B2, 40B3 may overlap one another on adjoining parts T_{RB}, T_{BG} in a vertical direction. In this case, each horizontal width of the adjoining parts T_{RB}, T_{BG} is approximately 0.8 micron to the approximately 1.2 microns, for example.

Moreover, in the layered color filter according to the first embodiment, it is preferable that the color filters of mutually different colors are disposed so as to adjoin to each other, as shown in FIGS. 7 and 8.

Moreover, in the layered color filter according to the first embodiment, it is preferable that the color filters of mutually different colors are alternately overlapped sequentially from the color filter to be disposed in the highest layer, as shown in FIG. 8. As an example shown in FIG. 8, the color filters 40R1, 40G1, 40B2, 40R2, 40G2, 40B3 of mutually different colors are alternately overlapped sequentially from the color filter 40B1 to be disposed in the highest layer.

In the layered color filter according to the first embodiment, in order to prevent color mixture occurring, adjoining parts T_{BB}, T_{BG} for color separating equivalent to the black matrix are formed between the adjoining sub pixels by the overlap effect of the color filters, without forming the black matrix.

As shown in FIGS. 7 and 8, the color filters adjoining to each other overlap one another on the adjoining parts T_{RB}, T_{BG} in a vertical direction. In this case, the vertical direction means an up-and-down direction in FIG. 8.

More specifically, the red color filter 40R (40R1, 40R2) and the blue color filter 40B (40B1, 40B2, 40B3) overlap one another on the adjoining parts T_{RB} in the vertical direction. Moreover, the blue color filter 40B (40B1, 40B2, 40B3) and the green color filter 40G (40G1, 40G2) overlap one another on the adjoining parts T_{BG} in the vertical direction.

Each pattern width W_{R}, W_{B}, W_{G} of the sub pixel on which the red color filters 40R, the blue color filters 40B, and the green color filters 40G are disposed is approximately 4.5 microns. Furthermore, the pattern width W_{R}, W_{B}, W_{G} of finer sub pixels may be respectively approximately 3 microns, approximately 4 microns, and approximately 3 microns. In this case, it is preferable to overlap the color filters one another on the adjoining parts T_{RB}, T_{BG} in a width from approximately 0.8 micron to the approximately 1.2 microns, for example. The adjoining parts T_{RB}, T_{BG} act a role equivalent to the black matrix, thereby preventing color mixture.

If light leaked from a color filter of a certain sub pixel passes through a color filter of an adjoining sub pixel, color mixture (crosstalk) will occur. The color mixture becomes a cause of reducing image quality, an NTSC ratio (color gamut), etc. of a display device.

In the layered color filter according to the first embodiment, light emitted from the inside of the organic EL layer 36 where the red color filter 40R is disposed is illustrated with the solid arrow, and does not reach the blue color filter 40B (40B1, 40B2, 40B3), as shown in FIG. 8. In FIG. 8, the dashed line indicates a part through which the light does not pass. Specifically, since light is shielded by the adjoining parts T_{RB}, the color mixture between R-B can be prevented. Since the light is similarly shielded by the adjoining parts T_{BG}, the color mixture between B-G can also be prevented.

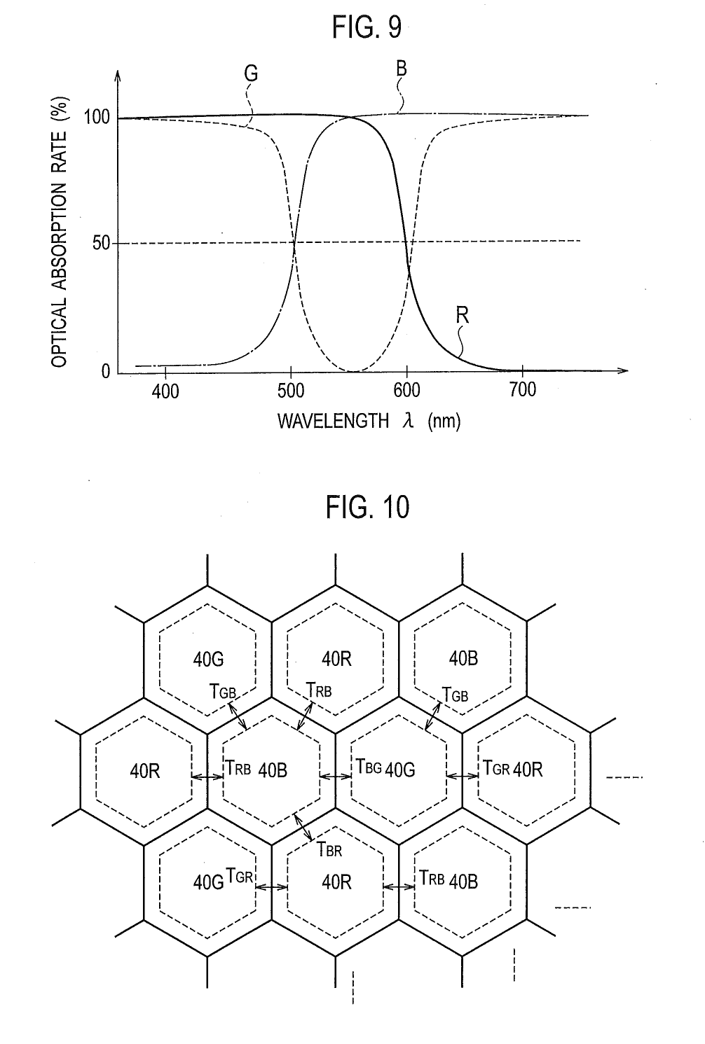

In the layered color filter according to the first embodiment, each relationship between an optical absorption rate and a wavelength of the red color filter, the green color filter, and the blue color filter is schematically illustrated with curved lines R, G, B, as shown in FIG. 9.

As shown in FIG. 9, the red color filter 40R allows the red light to pass through, but absorbs the light of the other colors. Moreover, the green color filter 40G allows the green light to pass through, but absorbs the light of the other colors. Furthermore, the blue color filter 40B allows the blue light to pass through, but absorbs the light of the other colors. Accordingly, if the color filters of the two colors allow the light to pass through, the optical absorption rate will become about 100% in almost all wavelength zones, thereby absorbing light of almost all colors. Specifically, if the color filters of the two colors allow the light to pass through, the light of almost all colors is absorbable.

In the layered color filter according to the first embodiment, as shown in FIG. 9, the overlap effect of the color filters achieves the color separating effect equivalent to that of the black matrix.

Although FIG. 8 shows the pixel structure of which the basic pattern is rectangular, other shaped pixel structure can also be applied as the basic pattern as already-explained.

FIG. 10 shows a schematic plane constitution of the layered color filter according to the first embodiment having an example of a delta arrangement pattern on the basis of a hexagon.

As shown in FIG. 10, in the layered color filter according to the first embodiment, the red color filter 40R, the green color filter 40G, and the blue color filter 40B may include a patter on the basis of a hexagon. In this case, as shown in FIG. 10, in each vertex part of the hexagon, the red color filter 40R, the green color filter 40G, and the blue color filter 40B overlap one another. However, if the basic pattern is the hexagon, the color filters of the mutually different colors can be disposed to always adjoin to each other. Accordingly, if the basic pattern is the hexagon, it is enabled to prevent color mixture with more sufficient accuracy, as compared with the case where the basic pattern is rectangular.

### (Fabrication Method of Layered Color Filter)

Hereinafter, there is described a fabrication method of the layered color filter according to the first embodiment, referring FIG. 6.

A fabrication method of the red color filter 40R (40R1, 40R2) is as follows. First, as shown in FIG. 6, a red color resist 40R1 is applied with thin film thickness (for example, 1 micron) on the upper electrode 38 to be exposed and developed. At this time, since ultraviolet light sufficiently reaches in a thickness direction, a predetermined degree of curing can be obtained. Subsequently, a red color resist 40R2 is applied again with thin film thickness (for example, approximately 1 micron) on the red color resist 40R1 to be exposed and developed. Also at this time, a predetermined degree of curing can be obtained in the same manner as the first layer.

A fabrication method of the green color filter 40G (40G1, 40G2) is the same as that of the red color filter. First, a green color resist 40G1 is applied with thin film thickness (for example, approximately 1 micron) on the upper electrode 38 to be exposed and developed. Subsequently, a green color resist 40G2 is applied again with thin film thickness (for example, approximately 1 micron) on the green color resist 40G1 to be exposed and developed.

In the layered color filter according to the first embodiment, the blue color filters 40B1, 40B2, 40B3 are formed in three layers, but the red color filters 40R1, 40R2 and the green color filters 40G1, 40G2 are respectively formed in two layers. Since it is hard to cure the blue color resist as compared with the other red color resist or green color resist, the number of times of overlapping the blue color resist is increased rather than that of the other red color resist and green color resist.

First, a blue color resist 40B1 is applied with thin film thickness (for example, approximately 0.8 micron) on the upper electrode 38 to be exposed and developed. Subsequently, a blue color resist 40B2 is applied again with thin film thickness (for example, approximately 0.8 micron) on the blue color resist 40B1 to be exposed and developed. Furthermore, the blue color resist 40B3 is applied with thin film thickness (for example, approximately 0.8 micron) on the blue color resist 40B2 to be exposed and developed.

The method of such an overlapped application is significant in obtaining a finer resist pattern (equal to or less than approximately 10 microns, in particular in a planar view). Specifically, if a resist shape is larger, a degree of curing at a bottom surface of the resist may become unsatisfactory. Even in such a case, heat curing again if the resist remains slightly at the time of the development, thereby obtaining the predetermined optical transparency and optical selectivity.

If alight source used is limited in particular as the case when an exposure machine is a stepper (reduction exposure system), it is difficult to cure effectively the resist. However, according to the method of the overlapped application, if a predetermined pattern can be formed even when using a stepper, it becomes enabled to also form a finer pattern equal to or less than approximately 5 micron, for example.

Moreover, according to the method of the overlapped application, the amount of dosage of the ultraviolet light irradiation used for the light-curing can be reduced. Accordingly, it becomes enabled to reduce an effect exerted on patterns except the color resist.

### Modified Example 1

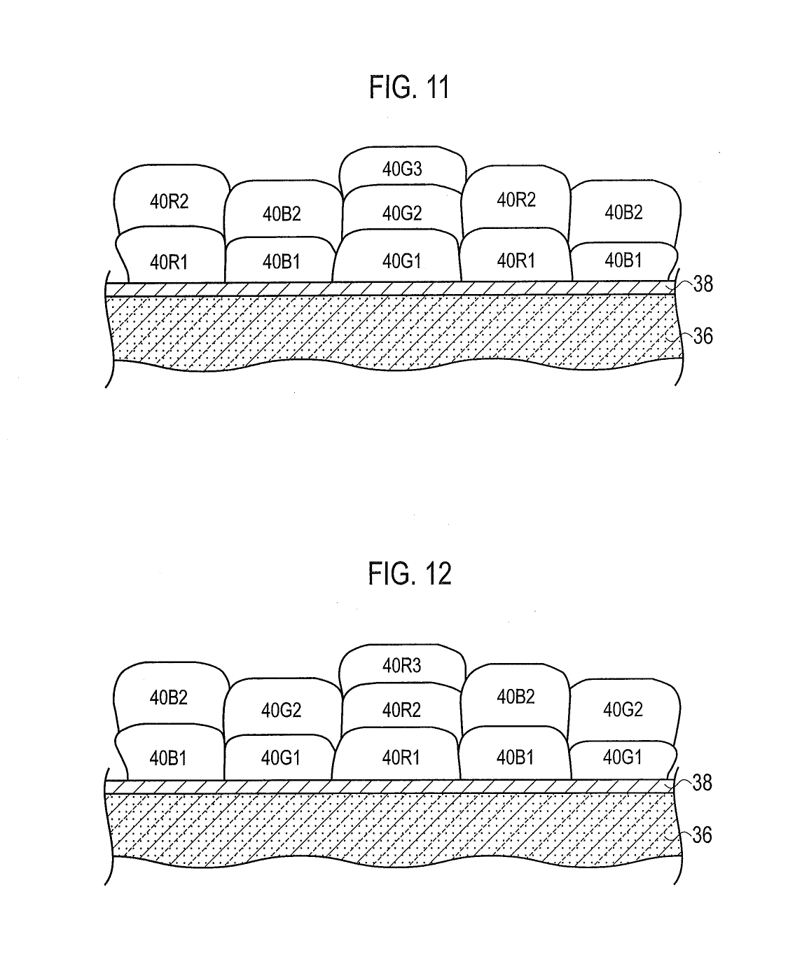

As shown in FIG. 11, a layered color filter according to a modified example 1 of the first embodiment includes: two-layer red color resists 40R1, 40R2; three-layer green color resists 40G1, 40G2, 40G3; and two-layer blue color resists 40B1, 40B2. Each film thickness of the color resists may be equal to or less than approximately 1 micron, for example. In this case, since the layer of the green color resists 40G1, 40G2, 40G3 is the highest layers, the color resists of mutually different colors are alternately overlapped sequentially from the green color resist 40G1.

In the layered color filter according to the modified example 1 of the first embodiment, each color filter can be relatively-thinly formed, and thereby the optical selectivity can be improved, without degrading the optical transparency.

### Modified Example 2

As shown in FIG. 12, a layered color filter according to a modified example 2 of the first embodiment includes: three-layer red color resists 40R1, 40R2, 40R3; two-layer green color resists 40G1, 40G2; and two-layer blue color resists 40B1, 40B2. Each film thickness of the color resists is not limited, and may be equal to or less than approximately 1 micron, for example. In this case, since the layer of the red color resists 40R1, 40R2, 40R3 is the highest layers, the color resists of mutually different colors are alternately overlapped sequentially from the red color resist 40R1.

In the layered color filter according to the modified example 2 of the first embodiment, each color filter can be relatively-thinly formed, and thereby the optical selectivity can be improved, without degrading the optical transparency.

### Modified Example 3

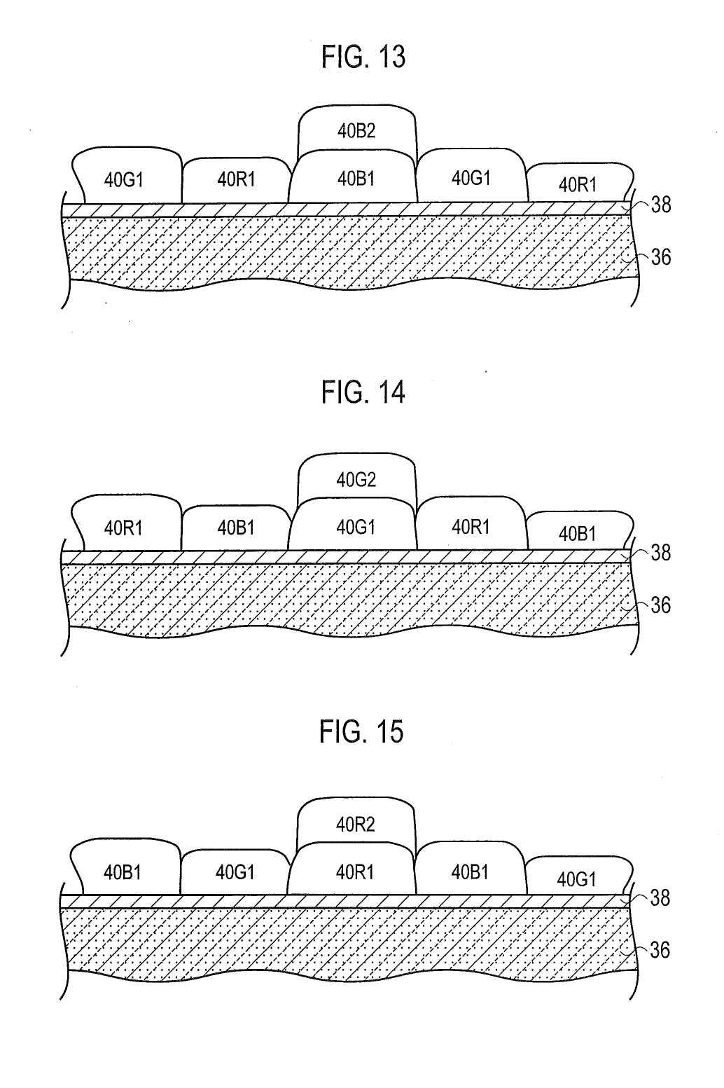

As shown in FIG. 13, a layered color filter according to a modified example 3 of the first embodiment includes: one-layer red color resist 40R1; one-layer green color resist 40G1; and two-layer blue color resists 40B1, 40B2. Each film thickness of the color resists may be equal to or less than approximately 1 micron, for example. In this case, since the layer of the blue color resists 40B1, 40B2 is the highest layers, the color resists of mutually different colors are alternately overlapped sequentially from the blue color resist 40B1.

In the layered color filter according to the modified example 3 of the first embodiment, each color filter can be relatively-thinly formed, and thereby the optical selectivity can be improved, without degrading the optical transparency.

### Modified Example 4

As shown in FIG. 1, a layered color filter according to a modified example 4 of the first embodiment includes: one-layer red color resist 40R1; two-layer green color resists 40G1, 40G2; and one-layer blue color resist 40B1. Each film thickness of the color resists may be equal to or less than approximately 1 micron, for example. In this case, since the layer of the green color resists 40G1, 40G2 is the highest layers, the color resists of mutually different color are alternately overlapped sequentially from the green color resist 40G1.

In the layered color filter according to the modified example 4 of the first embodiment, each color filter can be relatively-thinly formed, and thereby the optical selectivity can be improved, without degrading the optical transparency.

### Modified Example 5

As shown in FIG. 15, a layered color filter according to a modified example 5 of the first embodiment includes: two-layer red color resists 40R1, 40R2; one-layer green color resist 40G1; and one-layer blue color resist 40B1. Each film thickness of the color resists may be equal to or less than approximately 1 micron, for example. In this case, since the layer of the red color resists 40R1, 40R2 is the highest layers, the color resists of mutually different color are alternately overlapped sequentially from the red color resist 40R1.

In the layered color filter according to the modified example 5 of the first embodiment, each color filter can be relatively-thinly formed, and thereby the optical selectivity can be improved, without degrading the optical transparency.

### Modified Example 6

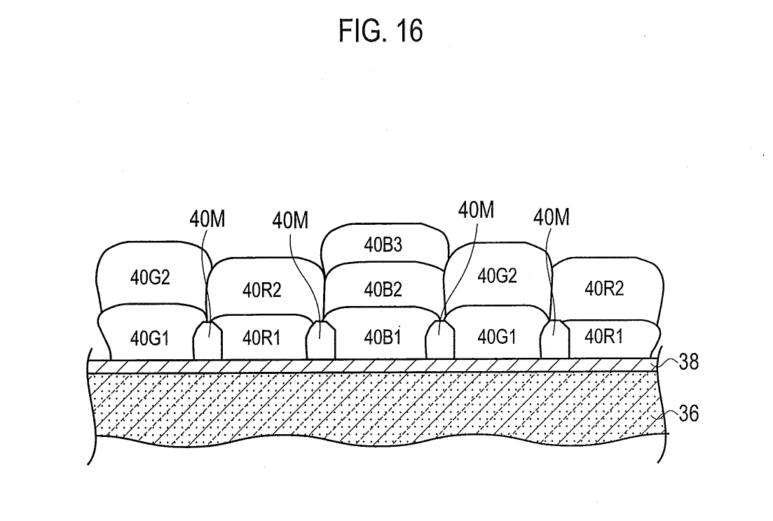

As shown in FIG. 16, a layered color filter according to a modified example 6 of the first embodiment includes: two-layer red color resists 40R1, 40R2; two-layer green color resists 40G1, 40G2; and three-layer blue color resists 40B1, 40B2, 40B3. Moreover, black color resists 40M are disposed on each adjoining part of the red color resist 40R1, the green color resist 40G1, and the blue color resist 40B1. The black color resist 40M acts a role of the black matrix for preventing the color mixture occurring.

In the layered color filter according to the modified example 6 of the first embodiment, the black color resists 40M for preventing color mixture may be disposed on each adjoining parts of the red color filter 40R1, the green color filter 40G1, and the blue color filter 40B1.

In the layered color filter according to the modified example 6 of the first embodiment, it is not necessary to overlap the adjoining color filters one another to be formed in the vertical direction. The thickness of the black color resist 40M may be approximately 0.8 micron, for example.

Since the layered color filter according to the modified example 6 of the first embodiment includes the black color resist 40M, even if the adjoining color filters are not overlapped one another in the vertical direction, the color mixture can be prevented.

Note that the film thickness or the number of layers of the color filter 40, and the arrangement pattern in a planar view are not limited to examples illustrated in the first embodiment and its modified examples 1-6. The performance can be improved as the number of layers is increased by forming with thin film thickness.

Moreover, although mainly illustrating the layered color filter according to the first embodiment and its modified examples 1-6 mounted on the organic electroluminescence display device, it is not limited to the examples. The layered color filter according to the first embodiment and its modified examples 1-6 can also be applied to various organic EL light emitting devices using organic EL, e.g. an organic EL lighting device.

### (Organic EL Light Emitting Device)

An organic EL light emitting device on which the layered color filter according to the first embodiment is mounted includes: in one pixel 6, a substrate 58; driver circuits 34R, 34G, 34B disposed on the substrate 58, lower electrodes 30 disposed on the driver circuits 34R, 34G, 34B; an organic EL layer 36 disposed in common on the lower electrodes 30, an upper electrode 38 disposed on the organic EL layer 36; and a red color filter 40R, a green color filter 40G, and a blue color filter 40B disposed on the upper electrode 38, in the same manner as the basic configuration shown in FIGS. 1-4. In this case, at least one color filter among the red color filter 40R, the green color filter 40G, and the blue color filter 40B is formed as a plurality of thin film layers. The organic EL light emitting device on which the layered color filter according to the first embodiment is mounted forms the organic EL device on LSI, and can be applied to a micro display which disperses the color of light with the color resist.

FIG. 17 shows a schematic cross-sectional structure of one pixel part of an organic EL light emitting device on which the layered color filter according to the first embodiment is mounted.

In the organic EL light emitting device according to the first embodiment, the substrate 58 is composed of an Si wafer, a glass, a gas barrier plastic film, etc. In this case, in the organic EL light emitting device according to the basic configuration, the substrate 58 is an Si wafer on which CMOSLSI 600 is formed. Moreover, the substrate 58 may be a glass substrate on which LSI composed of a thin film transistor (TFT) is formed, for example.

Specifically, as shown in FIG. 17, the lower electrodes 30R, 30B, 30G for red, green, and blue are disposed on the semiconductor wafer 60 on which the CMOSLSI 600 is formed.

The lower electrodes 30R, 30B, 30G can be formed of a metal, such as Al, Mo, Ag, and Pt, or alloys thereof (AlCu etc.), for example. Moreover, the lower electrodes 30R, 30B, 30G may be an anode material which becomes a hole injection material at the time of being oxidized. As metals which become the hole injection material at the time of being oxidized, Mo, V, Ru, InSn, etc. are applicable, for example. If the materials are oxidized, it will be respectively become to MoOₓ, VOₓ, RuOₓ, and ITO.

Moreover, Ti, Cr, TiN, Ni, Ta, W, etc. may be inserted as an adhesive layer between the lower electrodes 30R, 30B, 30G and the semiconductor wafer 60.

Moreover, the organic EL layer 36 for emitting white light is disposed on the lower electrodes 30R, 30B, 30G, for example. White may be formed in a combination of cyan and yellow.

Furthermore, the upper electrode 38 and the sealing layer 44 for protecting the organic EL device from water or oxygen are disposed on the organic EL layer 36.

Moreover, the upper electrode 38 is composed of metallic thin films (approximately 0.1 nm to approximately 50 nm in thickness), e.g. Al, Ag, and MgAg, or transparent electrodes (metallic oxide film), e.g. ITO, IZO (approximately 1 nm to approximately 500 nm in thickness).

A glass, ceramics, etc. are used as materials of the sealing layer 44. Moreover, since the sealing layer 44 acts as a function which dissipates heat to outside, it is preferable to use a sealing layer with higher coefficient of thermal conductivity. The sealing layer 44 can also be formed with polymeric materials including a sulfur atom. Moreover, the sealing layer 44 can be formed of SiN_{X}, SiOₓN_{y}, SiOₓ, AlOₓ, etc.

Furthermore, the red color resists 40R1, 40R2, the green color resists 40G1, 40G2, the blue color resists 40B1, 40B2, 40B3 are disposed on the sealing layer 44, for example. In this case, if the respective film thicknesses or the respective numbers of layers of the red color resist, the green color resist, and the blue color resist are different from each other, concavity and convexity can occur on the top surfaces of the color resists. Accordingly, the transparent protective film (transparent resist) 42 which does not include the pigment is formed on each color resist for the purpose of planarization.

### (Cross-Sectional SEM Photograph)

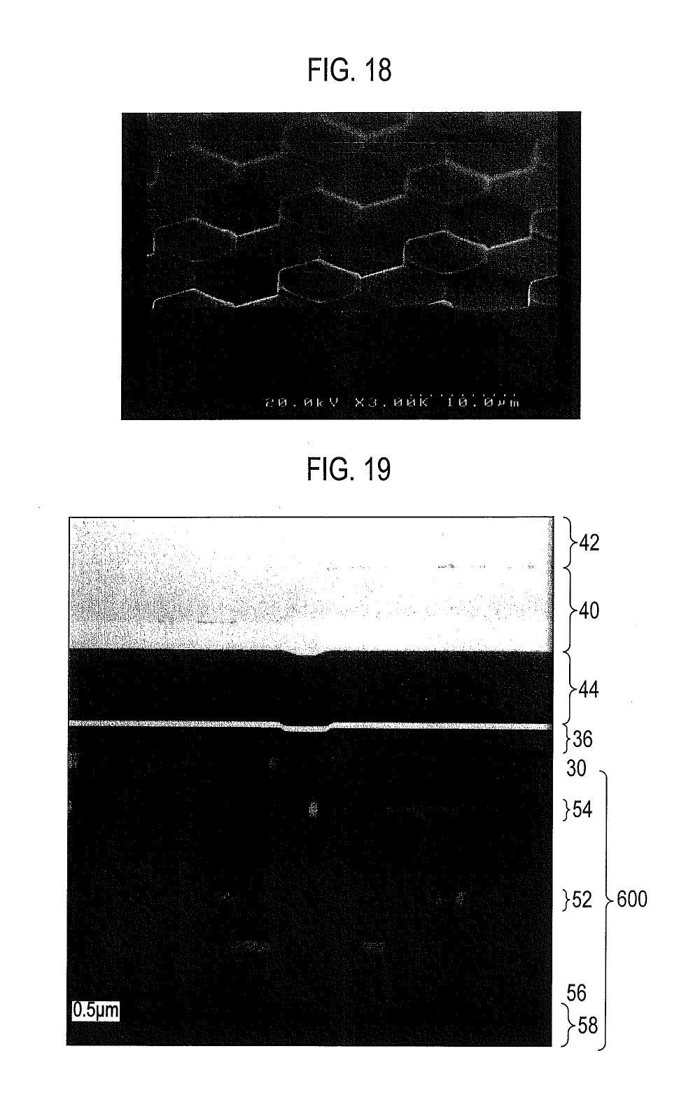

FIG. 18 shows a bird's-eye view surface SEM photograph example of the organic EL light emitting device on which the layered color filter according to the first embodiment is mounted. FIG. 18 shows an example of which the layered color filter on the basis of a hexagon is disposed on a sub pixel of which the basic pattern is a hexagon.

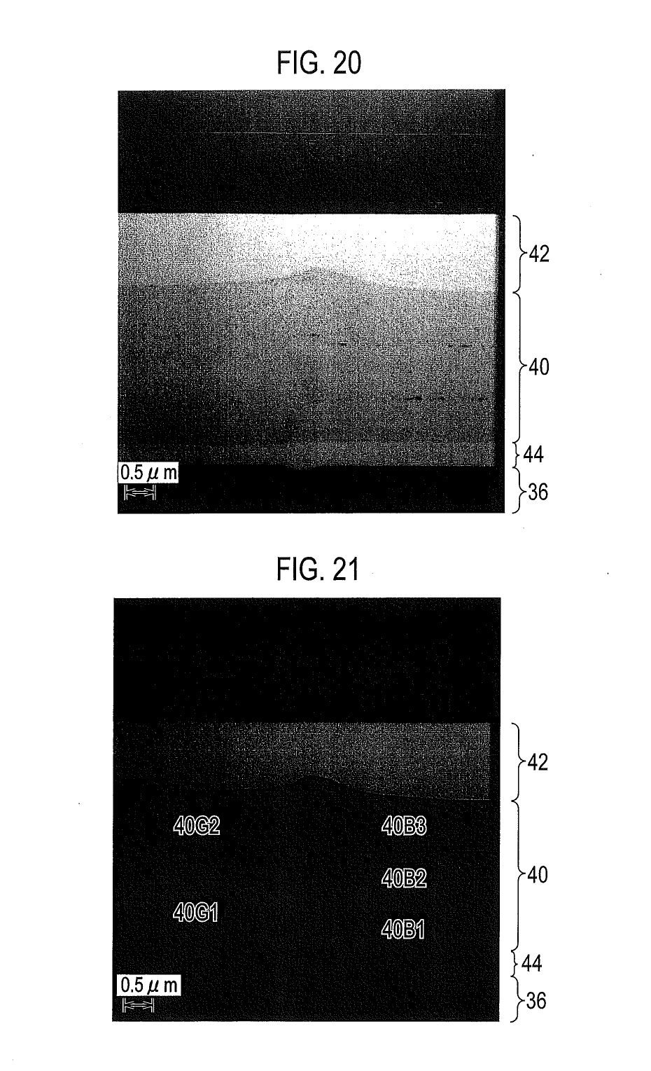

FIG. 19 shows a cross-sectional SEM photographs SEM photograph example of the organic EL light emitting device on which the layered color filter according to the first embodiment is mounted. Moreover, FIG. 20 shows an enlarged cross-sectional SEM photograph of the layered color filter portion shown in FIG. 19, and FIG. 21 shows a detailed explanatory diagram of the layered color filter portion shown in FIG. 20. FIG. 21 is a photograph in which border lines are added to the photograph of FIG. 20.

As shown in FIG. 19, the organic EL layer 36 is laminated via the lower electrode 30 on the CMOSLSI 600, and the color filter 40 and the transparent protective film 42 are further disposed on the organic EL layer 36 via the sealing layer 44.

As shown in FIG. 21, a tip of the green color resist 40G1 overlaps on a tip of the blue color resist 40B1. Similarly, the respective tips overlap one another in sequence of the green color resist 40G1, the blue color resist 40B2, the green color resist 40G2, and the blue color resist 40B3. The transparent protective film 42 is disposed on the green color resist 40G2 and the blue color resist 40B3 for the purpose of planarization.

In this case, since the layer of the blue color resists 40B1, 40B2, 40B3 is the highest layers, the color resists of mutually different colors are alternately overlapped sequentially from the blue color resist 40B1. However, the sequence of overlapping the color resist is not limited to this example. However, the configuration which overlaps the color resists of mutually different colors alternately is easy for manufacturing, and can improve the color separating performance, as compared with a configuration which continuously overlaps the color resists of the same color.

As mentioned above, since the color filter 40 is formed of a plurality of thin film layers in the first embodiment, there is no problem of the adhesibility even when forming whole color filters in larger film thickness. Accordingly, the optical selectivity can be improved, without degrading the optical transparency.

### (Fabrication Method of Organic EL Light Emitting Device)

A fabrication method of the organic EL light emitting device according to the first embodiment, the organic EL light emitting device including, in one pixel 6, a substrate 58, driver circuits 34R, 34G, 34B disposed on the substrate 58, lower electrodes 30 disposed on the driver circuits 34R, 34G, 34B; an organic EL layer 36 disposed in common on the lower electrodes 30, an upper electrode 38 disposed on the organic EL layer 36, and a red color filter 40R, a green color filter 40G, and a blue color filter 40B disposed on the upper electrode 38, the fabrication method includes: applying a color resist to be exposed and developed; and applying a color resist of the same color thereon again to be exposed and developed. In this case, at least one color filter among the color filters 40R, 40G, and 40B are formed as a plurality of thin film layers.

In the first embodiment, the color filter 40 is formed as a plurality of thin film layers through the overlapped application of the red color resist, the green color resist, and the blue color resist. The red color resist includes a pigment which absorbs blue and green. The green color resist includes a pigment which absorbs blue and red. The blue color resist includes a pigment which absorbs green and red.

Moreover, in the fabrication method of the organic EL light emitting device according to the first embodiment, the blue color filters may be formed so that the number of layers of the blue color filters is larger than the number of layers of the red color filters or the green color filters.

Moreover, in the fabrication method of the organic EL light emitting device according to the first embodiment, there may be formed two-layer red color filters, two-layer green color filters, and three-layer blue color filters.

Moreover, in the fabrication method of the organic EL light emitting device according to the first embodiment, the red color filter, the green color filter, and the blue color filters adjoining to each other may be formed so as to overlap one another in a vertical direction in the adjoining parts.

Moreover, in the fabrication method of the organic EL light emitting device according to the first embodiment, color filters of mutually different colors may alternately overlap sequentially from the color filter disposed in the highest layer.

As described above, according to the present invention, there can be provided the layered color filter which can improve optical selectivity, without reducing optical transparency, the organic EL light emitting device on which such a layered color filter is mounted, and the fabrication method of such an organic EL light emitting device.

### Second Embodiment

The same reference numeral is attached for the similar configuration as the organic EL light emitting device according to the basic configuration, and detailed explanation will be omitted. Note that the same reference numeral is used in particular in the following explanation, without distinguishing color resist and the color filter.

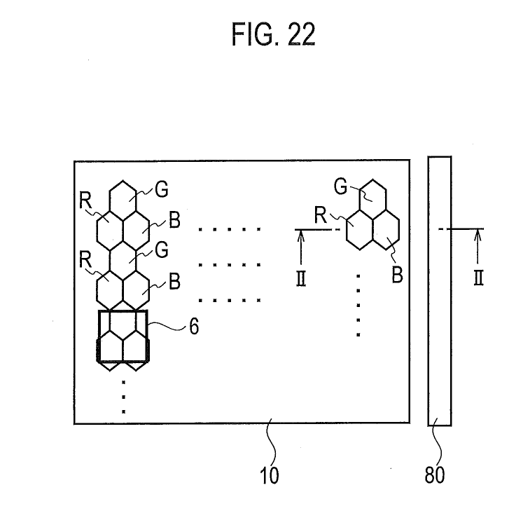

Hereinafter, a second embodiment will be described, referring FIGS. 22-24.

### (Organic EL Light Emitting Device)

An organic EL light emitting device according to the second embodiment includes: a substrate 58; driver circuits 34R, 34G, 34B disposed on and the substrate 58; anode VIA electrodes 70R, 70B disposed on the driver circuit 34R, 34G, 34B; lower electrodes 30R, 30B disposed on the anode VIA electrodes 70R, 70B; an organic EL layer 36 disposed in common on the lower electrodes 30R, 30B; an upper electrode 38 disposed in common on the organic EL layer 36; and a cathode VIA electrode 70C disposed on the substrate 58 and directly contacted to the upper electrode 38.

Note that although the lower electrode 30R for red and the lower electrode 30B for blue are illustrated and described herein, the lower electrode 30G for green (Green) is the same as the lower electrodes 30R and 30B. Naturally, the lower electrode 30G for green is disposed on the green anode VIA electrode 70G for green, and the anode VIA electrode 70G for green is disposed on the driver circuit 34G for green.

Moreover, the upper electrode 38 is formed as a common electrode.

In the organic EL light emitting device according to the first embodiment, the substrate 58 is composed of an Si wafer, a glass, a gas barrier plastic film, etc. In this case, in the organic EL light emitting device according to the basic configuration, the substrate 58 is an Si wafer on which CMOSLSI 600 is formed. Moreover, the substrate 58 may be a glass substrate on which LSI composed of a thin film transistor (TFT) is formed, for example.

Moreover, Ti, Cr, TiN, Ni, Ta, and W may be inserted in the lower part of the lower electrodes 30R, 30B as an adhesive layer with the substrate 58. Although illustrating is omitted, it is similar also about the lower electrode 30G.

Moreover, the upper electrode 38 is composed of metallic thin films (approximately 0.1 nm to approximately 50 nm in thickness), e.g. Al, Ag, and MgAg, or transparent electrodes (metallic oxide film), e.g. ITO, IZO (approximately 1 nm to approximately 500 nm in thickness).

### (Fabrication Method)

A fabrication method of the organic EL light emitting device according to the second embodiment, the organic EL light emitting device including a substrate 58, driver circuits 34R, 34G, 34B disposed on the substrate 58, anode VIA electrodes 70R, 70B disposed on the driver circuit 34R, 34G, 34B; lower electrodes 30R, 30B disposed on the anode VIA electrodes 70R, 70B; an organic EL layer 36 disposed in common on the lower electrodes 30R, 30B; an upper electrode 38 disposed in common on the organic EL layer 36; and a cathode VIA electrode 70C disposed on the substrate 58 and directly contacted to the upper electrode 38, the fabrication method includes: forming a dummy lower electrode 30C with the lower electrodes 30R, 30B on the substrate 58; removing the dummy lower electrode 30C; forming the organic EL layer 36 on the lower electrode 30R, 30B; and forming the upper electrode 38 on the organic EL layer 36 so as to be directly contacted to the cathode VIA electrode 70C. Although illustrating is omitted, a dummy lower electrode 30C is similarly formed and removed with respect to the lower electrode 30G.

### Fabrication Method

### Comparative Example 3

FIG. 22 shows a planar layout pattern configuration showing a pixel array 10 of an organic EL light emitting device according to a comparative example 3 and a perimeter thereof. An LSI contact unit 80 is disposed on a right-hand side of the pixel array 10 on the drawing. The LSI contact unit 80 is a part for connecting the upper electrode 38 to electric wiring of the CMOSLSI 600. The above-mentioned planar layout pattern configuration (FIG. 22) is similar not only to the comparative example 3, but also to the second to fifth embodiments.

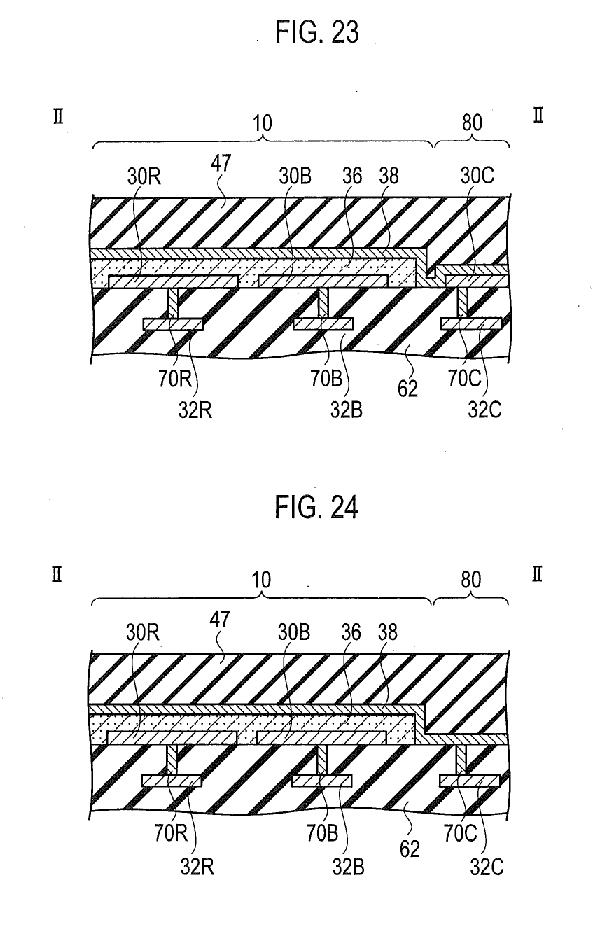

FIG. 23 shows a schematic cross-sectional structure taken in the line II-II of FIG. 22, in the organic EL light emitting device according to the comparative example 3.

As shown in FIG. 23, the lower electrodes 30R, 30B are formed on an insulating layer 62 of the pixel array 10. At this time, the dummy lower electrode 30C is formed also on the insulating layer 62 of the LSI contact unit 80. The dummy lower electrode 30C is formed with the lower electrodes 30R, 30B, and is a metallic material to only establish an electric contact with the cathode VIA electrode 70C. Hereinafter, the lower electrodes 30R, 30B and the dummy lower electrode 30C may be collectively called “lower electrode 30.”

Subsequently, the organic EL layer 36 is formed on the lower electrode 30R, 30B, and the upper electrode 38 is formed on the organic EL layer 36. The upper electrode 38 is contacted with the dummy lower electrode 30C in the LSI contact unit 80.

According to the comparative example 3, if the magnesium-silver alloy (MgAg) is used for the upper electrode 38, and molybdenum (Mo) is used for the lower electrode 30, an adhesibility between the upper electrode 38 and the lower electrode 30 is insufficient. There are Cr, Nb, Ru, and Ir as a metallic material which does not have sufficient adhesibility with MgAg except Mo. If the adhesibility between the upper electrode 38 and the lower electrode 30 is insufficient, contact resistance becomes higher, and a luminescent ability of the organic EL device is degraded.

### (Fabrication Method: Implementation Example)

FIG. 24 shows a schematic cross-sectional structure taken in the line II-II of FIG. 22, in the organic EL light emitting device according to the second embodiment.

As shown in FIG. 24, the anode VIA electrodes 70R, 70B are formed in the insulating layer 62 of the pixel array 10, and the cathode VIA electrode 70C is formed in the insulating layer 62 of the LSI contact unit 80. The anode VIA electrodes 70R, 70B are connected to the electric wirings 32R, 32B, and the cathode VIA electrode 70C is connected to the electric wiring 32C.

In this case, the insulating layer 62 is a silicon oxide film etc. formed on the surface of the substrate 58, if the substrate 58 is an Si wafer. Moreover, if the substrate 58 is composed of a gas barrier plastic film, a glass substrate, etc., the insulating layer 62 itself can be composed of a plastic film, a glass substrate, etc.

Subsequently, the lower electrodes 30R, 30B are formed on the insulating layer 62 of the pixel array 10. Specifically, a metal acting as the material of the lower electrodes 30R and 30B is patterned through film formation, photolithography, and dry etching, and then the resist is removed with ashing. At this time, the dummy lower electrode 30C is formed also on the insulating layer 62 of the LSI contact unit 80. The thickness of the lower electrodes 30R, 30B and the dummy lower electrode 30C is approximately 40 nm, for example.

Subsequently, the dummy lower electrode 30C is removed with etched at the time of forming the lower electrode 30R, 30B, the organic EL layer 36 is then formed on the lower electrode 30R, 30B, and the upper electrode 38 is then formed on the organic EL layer 36. At this time, as shown in FIG. 24, the upper electrode 38 is directly contacted to the cathode VIA electrode 70C, in the LSI contact unit 80. The term “directly” used herein means “without via the dummy lower electrode 30C.” Finally, the sealing film 47 is formed on the upper electrode 38, and then the organic EL device is completed.

As mentioned above, according to the second embodiment, the upper electrode 38 is directly contacted to the cathode VIA electrode 70C. Therefore, even if the adhesibility between the upper electrode 38 and the lower electrode 30 is insufficient, since the adhesibility between the cathode VIA electrode 70C and the upper electrode 38 is sufficient, the contact resistance can be reduced, thereby improving the luminescent characteristics of the organic EL device. Accordingly, a material in which the adhesibility with the upper electrode 38 is insufficient can be used as the lower electrode 30, and extending a range of choices of the lower electrode 30.

According to the second embodiment, there can be provided an organic EL light emitting device in which a luminescent ability and a manufacturing yield can be improved, and a fabrication method of such an organic EL light emitting device.

### Third Embodiment

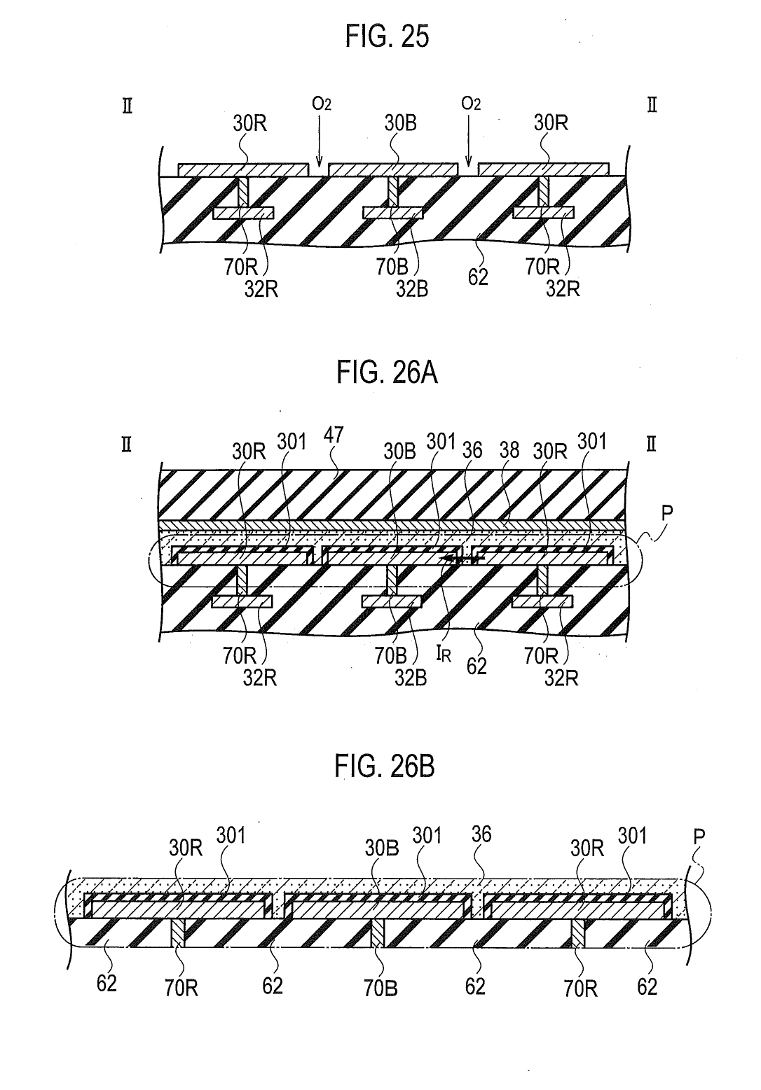

Hereinafter, a third embodiment will be described, referring FIGS. 25-28.

The surface of the lower electrodes 30R, 30B may be polluted with organic substances in a process or the atmospheric air, or the wettability against organic substances of the surface of the lower electrodes 30R, 30B may become higher. In such a case, a particle diameter of the organic EL layer 36 becomes larger, and leakage current I_{R} between the lower electrode 30R, 30B becomes higher. Therefore, a non-driven pixel emits light, thereby degrading the luminescent ability of the organic EL device.

### (Fabrication Method: Electrode Formation Method)

A fabrication method of the organic EL light emitting device according to the third embodiment, the organic EL light emitting device including a substrate 58, driver circuits 34R, 34G, 34B disposed on the substrate 58, anode VIA electrodes 70R, 70B disposed on the driver circuit 34R, 34G, 34B, lower electrodes 30R, 30B disposed on the anode VIA electrodes 70R, 70B, an organic EL layer 36 disposed in common on the lower electrodes 30R, 30B, an upper electrode 38 disposed in common on the organic EL layer 36; and a cathode VIA electrode 70C disposed on the substrate 58, the fabrication method includes: preparing the substrate 58; forming the lower electrodes 30R, 30B on the substrate 58; processing the substrate surface, forming the organic EL layer 36 on the lower electrode 30R, 30B; and forming the upper electrode 38 on the organic EL layer 36. Although illustrating is omitted, the surface of the lower electrode 30G is processed similarly.

### (Fabrication Method: Implementation Example)

FIGS. 25 and 26A show a schematic cross-sectional structure taken in the line II-II of FIG. 22, in the organic EL light emitting device according to the third embodiment. Moreover, FIG. 26B shows a schematic enlarged structure of a part P shown in FIG. 26A.

As shown in FIG. 25, after forming the anode VIA electrodes 70R, 70B connected to the electric wirings 32R, 32B in the insulating layer 62, the lower electrodes 30R, 30B are formed. Here, a processing step of processing the substrate surface (e.g., processing with O₂ plasma or UV ozone) is added before the processing step of the forming of the organic EL layer 36.

Accordingly, as shown in FIGS. 26A and 26B, a metallic oxide film 301 is formed on the surface of the lower electrodes 30R, 30B. For example, if the material of the lower electrodes 30R, 30B is Mo, the metallic oxide film 301 is MoO₂ or MoO₃. The film thickness of the metallic oxide film 301 is controlled to suitable film thickness by setting suitably conditions for processing the substrate surface. By forming such a metallic oxide film 301, contaminants on the surface of the lower electrodes 30R, 30B can be removed, or the wettability against organic substances on the surface of the lower electrodes 30R, 30B can be reduced. As a result, the leakage current I_{R} between the lower electrodes 30R, 30B is reduced, thereby improving the luminescent characteristics of the organic EL device.

(Leakage Current between Lower Electrodes)

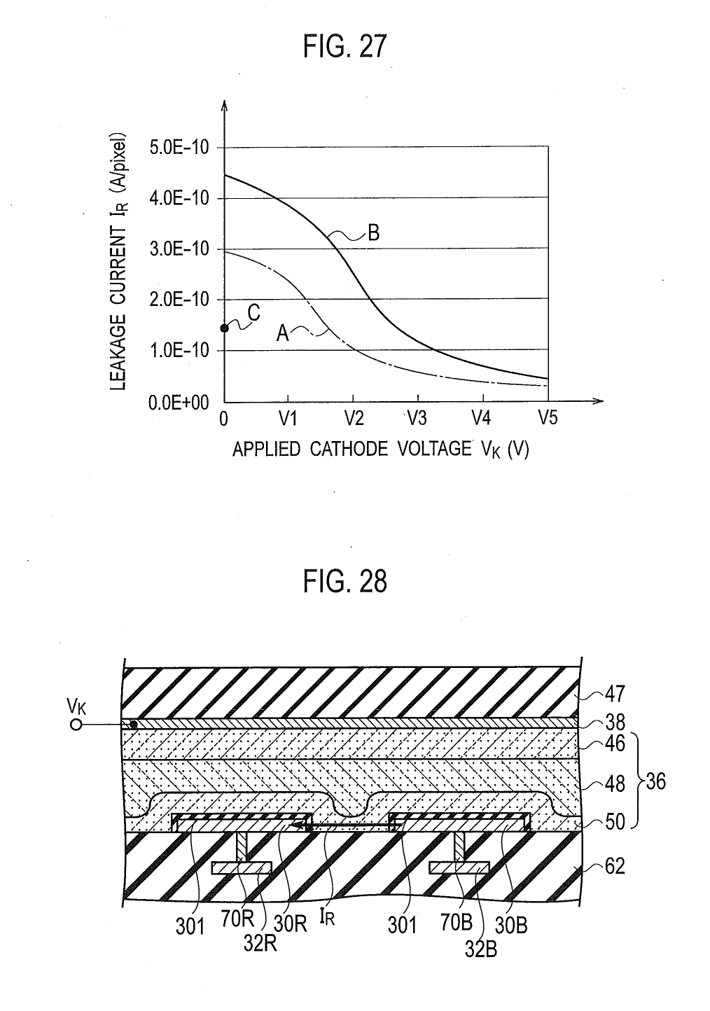

FIG. 27 shows a graphic chart showing leakage current I_{R} between the lower electrodes 30R, 30B of the organic EL light emitting device according to the third embodiment, and leakage current I_{R} between the lower electrodes 30R, 30B of the organic EL light emitting device according to the comparative example 3.

In the graphic chart of FIG. 27, the axis of ordinate indicates leakage current I_{R} (A/pixel) between the lower electrodes 30R, 30B. The axis of abscissa indicates applied cathode voltage V_{K} (V), and the voltage value become larger toward the right side. The curve A indicates the third embodiment, the curve B indicates the comparative example 3, and the reference numeral C indicates a targeted value. As shown in the graphic chart, according to the third embodiment (curve A), the leakage current I_{R} is reduced, thereby approaching the targeted value C, as compared with the comparative example 3 (curve B).

As mentioned above, in the third embodiment, the step of processing the substrate surface is inserted between the step of forming the lower electrodes 30R, 30B and the step of forming the organic EL layer 36. Accordingly, since the metallic oxide film 301 is formed on the surface of the lower electrodes 30R, 30B, contaminants on the surface of the lower electrodes 30R, 30B can be removed, or the wettability against the organic substance on the surface of the lower electrodes 30R, 30B can be reduced. As a result, the leakage current I_{R} between the lower electrodes 30R, 30B is reduced, thereby improving the luminescent characteristics of the organic EL device.

According to the third embodiment, there can be provided an organic EL light emitting device in which a luminescent ability and a manufacturing yield can be improved, and a fabrication method of such an organic EL light emitting device.

FIG. 28 shows a schematic cross-sectional structure for explaining the leakage current I_{R} between the lower electrodes 30R, 30B, and the applied cathode voltage V_{K} of the organic EL light emitting device according to the third embodiment.

As shown in FIG. 28, the leakage current I_{R} is an electric current which flows between the lower electrodes 30R, 30B.

The applied cathode voltage V_{K} is voltage applied between the upper electrode 38 and the lower electrodes 30R, 30B via the electron transport layer 46 and the hole transport layer 50 of the organic EL layer 36.

As proved from FIG. 27, the electric current I_{R} which flows between the lower electrodes 30R, 30B is controllable by the applied cathode voltage V_{K}. Specifically, there can be formed a p-channel transistor in which the lower electrodes 30R, 30B are applied to a source/drain, the upper electrode 38 is applied to a gate or a back gate, and the hole transport layer 50 of the organic EL layer 36 is applied to a channel. Such a MOS transistor is available as a transistor used for a driver circuit or control circuit of the organic EL light emitting device according to the third embodiment.

### Fourth Embodiment

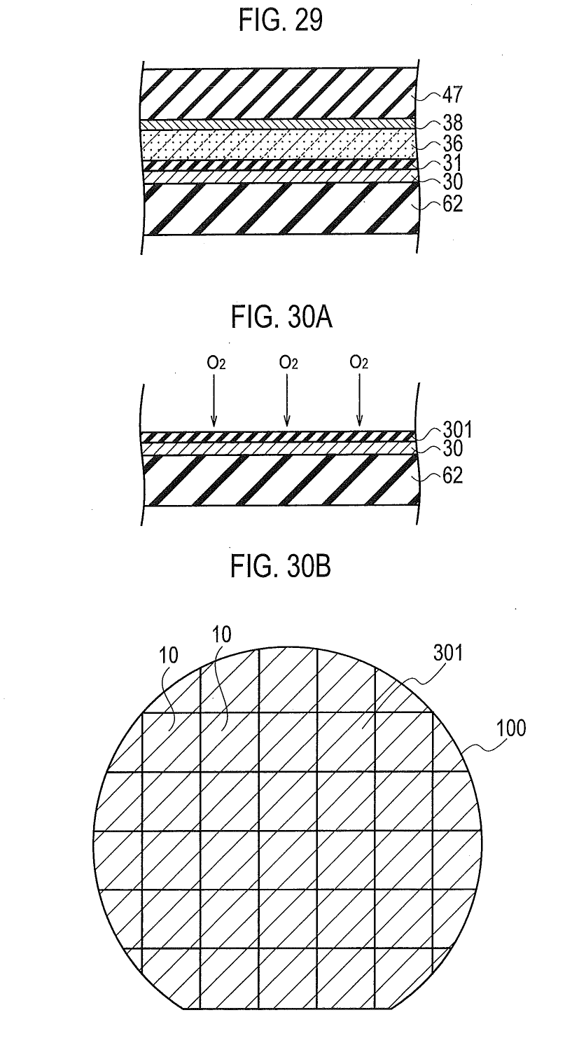

Hereinafter, a fourth embodiment will be described, referring FIGS. 29-30.

### (Organic EL Light Emitting Device)

An organic EL light emitting device according to the fourth embodiment includes: a substrate 58; driver circuits 34R, 34G, 34B disposed on the substrate 58; anode VIA electrodes 70R, 70B disposed on the driver circuit 34R, 34G, 34B; lower electrodes 30R, 30B disposed on the anode VIA electrodes 70R, 70B, and having a metallic oxide film 301 on a surface thereof; an organic EL layer 36 disposed in common on the lower electrodes 30R, 30B; an upper electrode 38 disposed in common on the organic EL layer 36; and a cathode VIA electrode 70C disposed on the substrate 58. In this case, the lower electrodes 30R, 30B are metallic materials which become a hole injection material at the time of being oxidized, and have the metallic oxide film 301 formed on the surface thereof, during atmospheric anneal process or UV ozonization process. The lower electrode 30G is the same as the lower electrodes 30R, 30B.

Moreover, the lower electrodes 30R, 30B may be metallic materials which become a hole injection material at the time of being oxidized. The lower electrode 30G is the same as the lower electrodes 30R, 30B.

Moreover, the metallic oxide film 301 may be formed on the surface of the lower electrodes 30R, 30B, during the atmospheric anneal process or the UV ozonization process. The lower electrode 30G is the same as the lower electrodes 30R, 30B.

Moreover, the lower electrodes 30R, 30B may be formed of one of Mo, V, Ru, or InSn. As metals which become the hole injection material at the time of being oxidized, Mo, V, Ru, InSn, W, etc. are applicable, for example. If the above-mentioned materials are oxidized, it will be respectively become to MoOₓ, VOₓ, RuOₓ, ITO, and WOₓ. The lower electrode 30G is the same as the lower electrodes 30R, 30B.

The lower electrodes 30R, 30B can also be composed of high-reflectivity metals, e.g. Mo, Al, Ag, or Pt. Moreover, the lower electrodes 30R, 30B may also be composed of alloys (AlCu etc.) composed of the above-mentioned high-reflectivity metals as a main constituent. The lower electrode 30G is the same as the lower electrodes 30R, 30B.

### (Fabrication Method: Electrode Formation Method)

In a fabrication method of the organic EL light emitting device according to the fourth embodiment, the lower electrodes 30R, 30B are the metallic materials which become the hole injection material at the time of being oxidized. The lower electrode 30G is the same as the lower electrodes 30R, 30B.

Moreover, the step of processing the substrate surface may also include the step of oxidizing the surface of the lower electrodes 30R, 30B during the atmospheric anneal process or the UV ozonization process. The lower electrode 30G is the same as the lower electrodes 30R, 30B.

FIG. 29 shows a schematic cross-sectional structure for explaining a fabrication method of the organic EL light emitting device according to the comparative example 3.

As shown in FIG. 29, a metal layer which is a material for the lower electrode 30 is formed on the insulating layer 62, and the metallic oxide film 31 is formed on the metal layer during vacuum evaporation or sputtering. Furthermore, the organic EL layer 36 is formed on the metallic oxide film 31, the upper electrode 38 is formed on the organic EL layer 36, and the sealing film 47 is formed on the upper electrode 38. According to the comparative example 3, since an apparatus for forming the metallic oxide film 31 is a vacuum apparatus, it is difficult to correspond with upsizing of the substrate 58, and the cost also rises.

### (Fabrication Method: Implementation Example)

FIG. 30A shows a schematic cross-sectional structure for explaining a fabrication method of the organic EL light emitting device according to the fourth embodiment. Moreover, FIG. 30B shows a schematic planar structure of an Si wafer 100 for explaining the fabrication method of the organic EL light emitting device according to the fourth embodiment.

As shown in FIG. 30A, a metal layer which is a material for the lower electrode 30 is formed on the insulating layer 62, and then atmospheric anneal process or UV ozonization process is performed on a hot plate or in an oven. The atmospheric anneal processes is preferable to perform at approximately 130 degrees C. to approximately 180 degrees C. for approximately 10 minutes to approximately 1 hour, for example, and the UV ozonization process is preferable to perform for approximately 10 minutes to approximately 1 hour, for example. Such an atmospheric anneal processor UV ozonization process is performed in the state where plenty of the pixel arrays 10 are arranged on the Si wafer 100, as shown in FIG. 30B. Accordingly, the surface of the metal layer which is a material for the lower electrode 30 can be oxidized, thereby forming the metallic oxide film 301 acting as a hole injection material.

Specifically, anode material which becomes the hole injection material at the time of being oxidizing are used for the lower electrode 30. As metals which become the hole injection material at the time of being oxidized, Mo, V, Ru, InSn, etc. are applicable, for example. If the materials are oxidized, it will be respectively become to MoOₓ, VOₓ, RuOₓ, and ITO.

Although illustrating is omitted, after forming the metallic oxide film 301, the organic EL layer 36 is formed on the metallic oxide film 301. Furthermore, the upper electrode 38 is formed on the organic EL layer 36, and the sealing film 47 is formed on the upper electrode 38.

As mentioned above, in the fourth embodiment, the lower electrode 30 is a metallic material which becomes hole injection material at the time of being oxidized, and have the metallic oxide film 301 formed on the surface thereof, during the atmospheric anneal process or the UV ozonization process. Accordingly, since it does not need to use a vacuum apparatus for forming the metallic oxide film 31, it is easy to correspond with upsizing of the substrate 58, and the cost can also be reduced.

According to the fourth embodiment, there can be provided an organic EL light emitting device in which a luminescent ability and a manufacturing yield can be improved, and a fabrication method of such an organic EL light emitting device.

### Fifth Embodiment

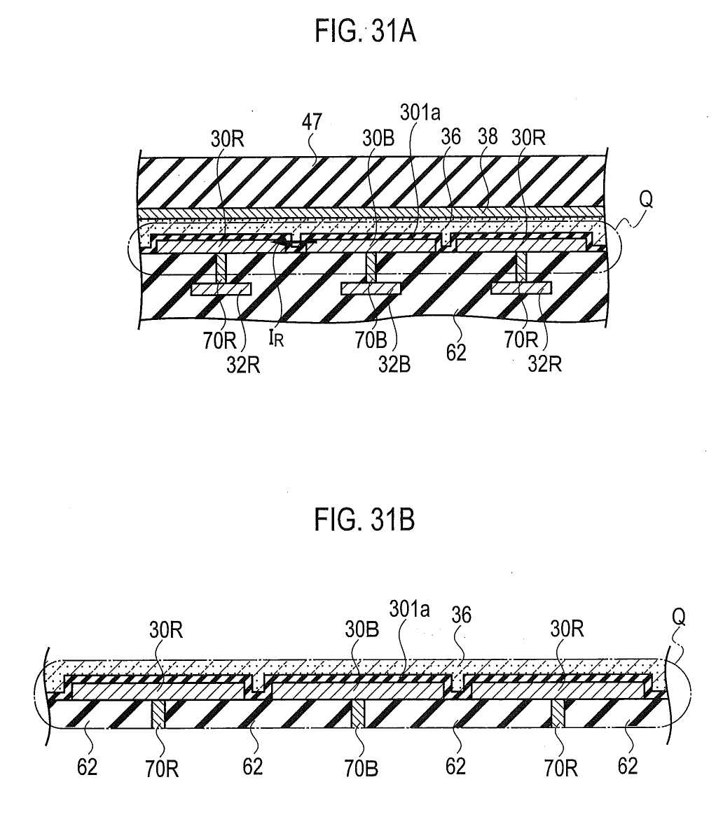

Hereinafter, a fifth embodiment will be described, referring FIGS. 31-35.

### (Organic EL Light Emitting Device)

In an organic EL light emitting device according to the fifth embodiment, a hole injection material is formed on the surface of the lower electrodes 30R, 30B. Although illustrating is omitted, the hole injection material is formed also on the surface of the lower electrode 30G.

Moreover, the hole injection material may be a metallic oxide film 301 for the lower electrodes 30R, 30B. Although illustrating is omitted, it is similar also about the lower electrode 30G.

Moreover, a MOS transistor is formed between each sub pixel in the pixel array 10 of the organic EL light emitting device.

Moreover, such a MOS transistor may be a driving transistor for the pixel array 10.

### Fabrication Method

### Comparative Example 3

FIG. 31A shows a schematic cross-sectional structure for explaining a fabrication method of the organic EL light emitting device according to a comparative example 3. Moreover, FIG. 31B shows a schematic enlarged structure of a part Q shown in FIG. 31A.

As shown in FIG. 31, the lower electrodes 30Rm 30B are formed on the insulating layer 62, and a hole injection material 301a is formed on a whole top surface thereof. Furthermore, the organic EL layer 36 is formed on the hole injection material 301a, the upper electrode 38 is formed on the organic EL layer 36, and the sealing film 47 is formed on the upper electrode 38. According to the comparative example 3, leakage current I_{R} between lower electrodes 30R, 30B becomes higher due to the hole injection material 301a between the lower electrodes 30R, 30B. Therefore, a non-driven pixel emits light, thereby degrading the luminescent ability of the organic EL device.

### (Fabrication Method: Illustrative Example)

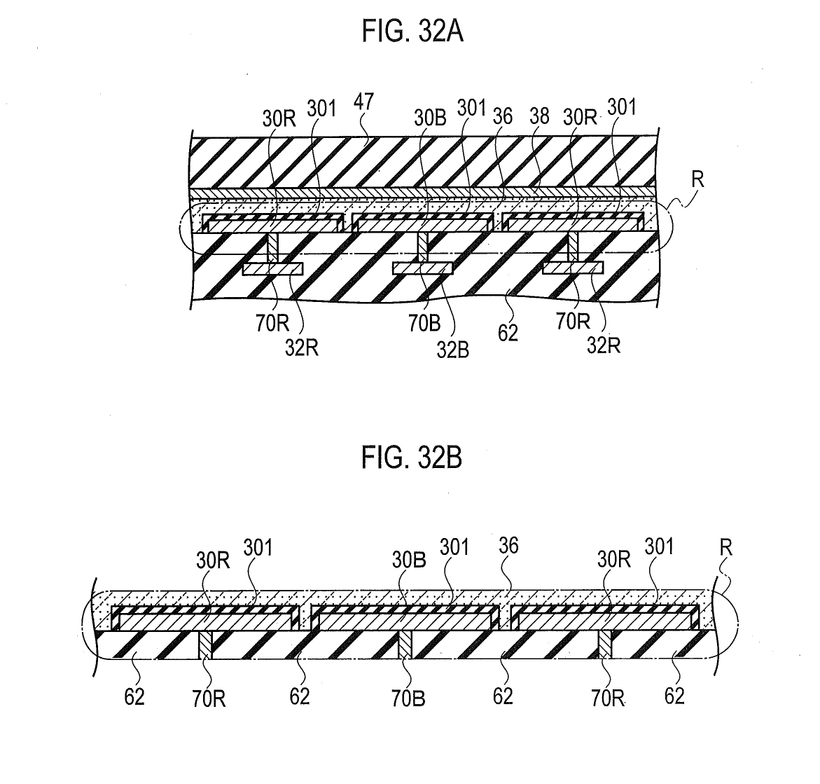

FIG. 32A shows a schematic cross-sectional structure for explaining a fabrication method of the organic EL light emitting device according to the fifth embodiment. Moreover, FIG. 32B shows a schematic enlarged structure of a part R shown in FIG. 32A.

As shown in FIG. 32, the lower electrodes 30R, 30B are formed on the insulating layer 62. At this time, the hole injection material is formed on the surface of the lower electrodes 30R, 30B. More specifically, a metallic material (e.g., Mo, V) which becomes a hole injection material at the time of being oxidized is used as the lower electrodes 30R, 30B to be patterned. Subsequently, the surface of the lower electrodes 30R, 30B is oxidized, and then the metallic oxide film 301 which becomes the hole injection material is formed. Furthermore, the organic EL layer 36 is formed on the metallic oxide film 301, the upper electrode 38 is formed on the organic EL layer 36, and the sealing film 47 is formed on the upper electrode 38.

Accordingly, no hole injection material is formed between the lower electrodes 30R, 30B. As a result, the leakage current I_{R} between the lower electrodes 30R, 30B is reduced, thereby improving the luminescent characteristics of the organic EL device.

(Leakage Current between Lower Electrodes)

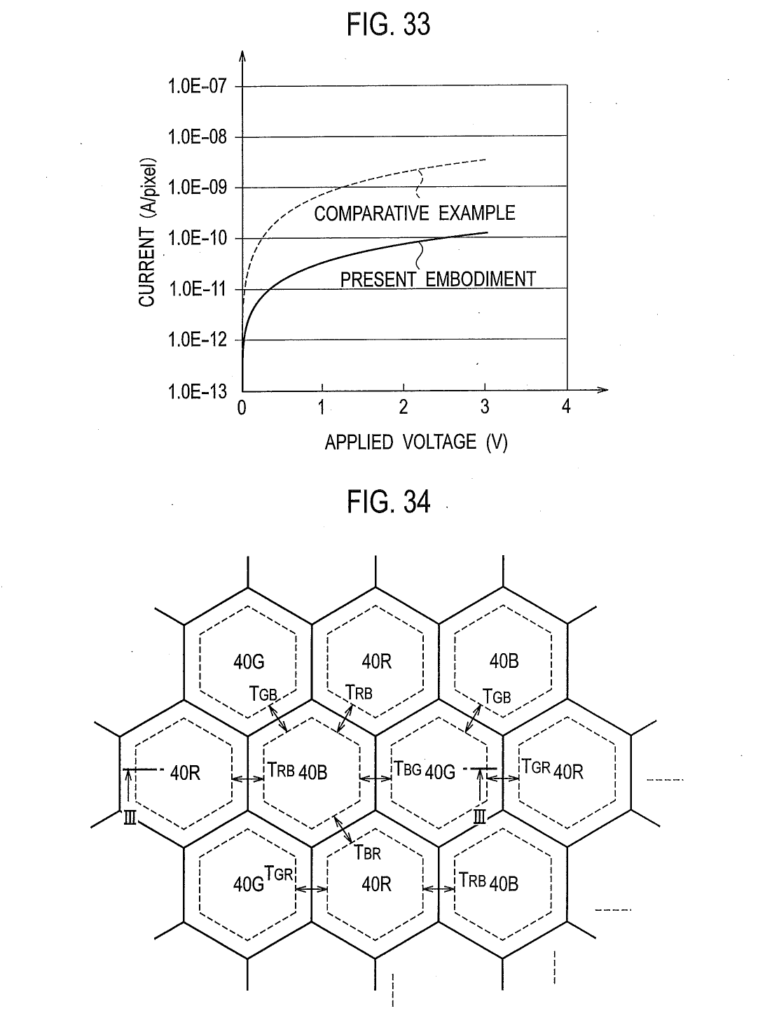

FIG. 33 shows a graphic chart showing leakage current I_{R} between the lower electrodes 30R, 30B of the organic EL light emitting device according to the fifth embodiment, and leakage current I_{R} between the lower electrodes 30R, 30B of the organic EL light emitting device according to the comparative example 3.

In the graphic chart of FIG. 33, the axis of ordinate indicates leakage current I_{R} (A/pixel) between the lower electrodes 30R, 30B. The axis of abscissa is applied voltage (V) between anodes (the lower electrodes 30R, 30B). The curve drawn with the dotted line indicates the comparative example 3, and the curve drawn with the solid line indicates the fifth embodiment. As shown in the aforementioned graphic chart, according to the fifth embodiment, the leakage current I_{R} is reduced as compared with the comparative example 3.

### (MOS Transistor)

In the organic EL light emitting device according to the fifth embodiment, the metallic oxide film 301 which becomes a hole injection material is formed on the surface of the lower electrodes 30R, 30G, 30B.

The electric current I_{R} which flows between the lower electrodes 30R, 30B is controllable by the applied cathode voltage V_{K}. Specifically, there can be formed a p-channel transistor in which the lower electrodes 30R, 30B are applied to a source/drain, the upper electrode 38 is applied to a gate or a back gate, and the hole transport layer 50 of the organic EL layer 36 is applied to a channel, as explained in the third embodiment. Moreover, such a MOS transistor is available as a driving transistor for the pixel array 10.

### (Layered Color Filter)

FIG. 34 shows a schematic plane constitution of a layered color filter mounted on the organic EL light emitting device according to the fifth embodiment, the layered color filter having an example of a delta arrangement pattern on the basis of hexagon.

As shown in FIG. 34, in the layered color filter according to the fifth embodiment, the red color filter 40R, the green color filter 40G, and the blue color filter 40B may include a patter on the basis of a hexagon. In this case, as shown in FIG. 34, in each vertex part of the hexagon, the red color filter 40R, the green color filter 40G, and the blue color filter 40B overlap one another. If rectangular is applied as the basic pattern, the adjoining color filters may become the same color. On the other hand, if hexagon is applied as the basic pattern, the color filters adjoining to each other can be arranged to always be mutually different colors. Accordingly, if the basic pattern is the hexagon, it is enabled to prevent the color mixture with more sufficient accuracy, as compared with the case where the basic pattern is rectangular.

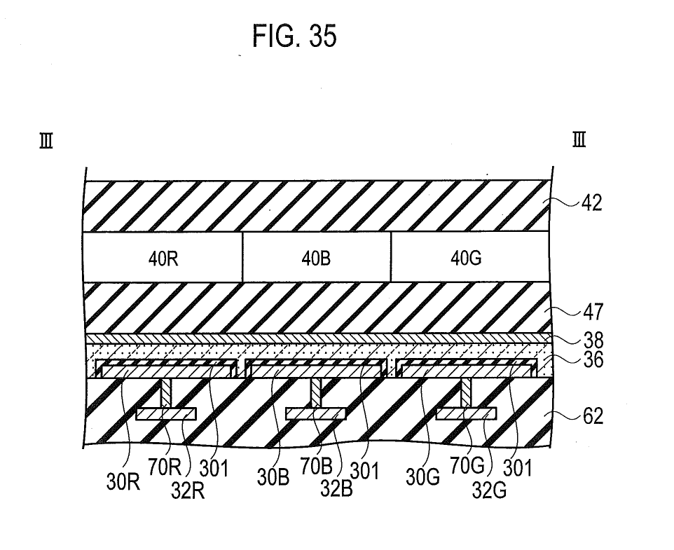

FIG. 35 shows a schematic cross-sectional structure taken in the line III-III of FIG. 34, in the organic EL light emitting device according to the fifth embodiment.

In FIG. 35, the electric wirings 32R, 32G, 32B respectively indicate electric wirings 32 for red, green, and blue. The anode VIA electrodes 70R, 70G, 70B respectively indicate anode VIA electrodes 70 for red, green, and blue. The lower electrodes 30R, 30G, 30B indicate respectively lower electrodes 30 for red, green, and blue. The metallic oxide film 301 is formed on each surface of the lower electrodes 30R, 30G, 30B, and the organic EL layer 36, the upper electrode 38, and the sealing film 47 are formed thereon. The red color filter 40R, the green color filter 40G, and the blue color filter 40B are formed on the sealing film 47, and the transparent protective film 42 is further disposed thereon.

As mentioned above, the hole injection material is formed on the surface of the lower electrodes 30R, 30G, 30B, in the fifth embodiment. Specifically, no hole injection material is formed between the lower electrodes 30R, 30G, 30B. As a result, the leakage current IR between the lower electrodes 30R, 30G, 30B is reduced, thereby improving the luminescent characteristics of the organic EL device.

According to the fifth embodiment, there can be provided an organic EL light emitting device in which a luminescent ability and a manufacturing yield can be improved, and a fabrication method of such an organic EL light emitting device.

### [Cross-Sectional SEM Photograph]

FIG. 18 shows an example of a bird's-eye view surface SEM photograph of the organic EL light emitting device according to the second to sixth embodiments on which the layered color filter is mounted. FIG. 18 shows an example of which the layered color filter on the basis of a hexagon is disposed on a sub pixel of which the basic pattern is a hexagon.

FIG. 19 shows an example of a cross-sectional SEM photograph of the organic EL light emitting device according to the second to sixth embodiments on which the layered color filter is mounted. Moreover, FIG. 20 shows an enlarged cross-sectional SEM photograph of the layered color filter portion shown in FIG. 19, and FIG. 22 shows a detailed explanatory diagram of the layered color filter portion shown in FIG. 20. FIG. 22 is a photograph in which border lines are added to the photograph of FIG. 20.

As shown in FIG. 19, the organic EL layer 36 is laminated via the lower electrode 30 on the CMOSLSI 600, and the color filter 40 and the transparent protective film 42 are further disposed on the organic EL layer 36 via the sealing layer 44.

As shown in FIG. 21, a tip of the green color resist 40G1 overlaps on a tip of the blue color resist 40B1. Similarly, the respective tips overlap one another in sequence of the green color resist 40G1, the blue color resist 40B2, the green color resist 40G2, and the blue color resist 40B3. The transparent protective film 42 is disposed on the green color resist 40G2 and the blue color resist 40B3 for the purpose of planarization.

In this case, since the layer of the blue color resists 40B1, 40B2, 40B3 is the highest layers, the color resists of the mutually different color are alternately overlapped sequentially from the blue color resist 40B1. However, the sequence of overlapping the color resists is limited to the aforementioned example. However, the configuration which overlaps the color resists of the mutually different colors alternately is easy for manufacturing, and can improve the color separating performance, as compared with a configuration which continuously overlaps the color resists of the same color.

### Sixth Embodiment

The same reference numeral is attached for the similar configuration as the organic EL light emitting device according to the basic configuration, and detailed explanation will be omitted. Note that the same reference numeral is used in particular in the following explanation, without distinguishing color resist and the color filter.

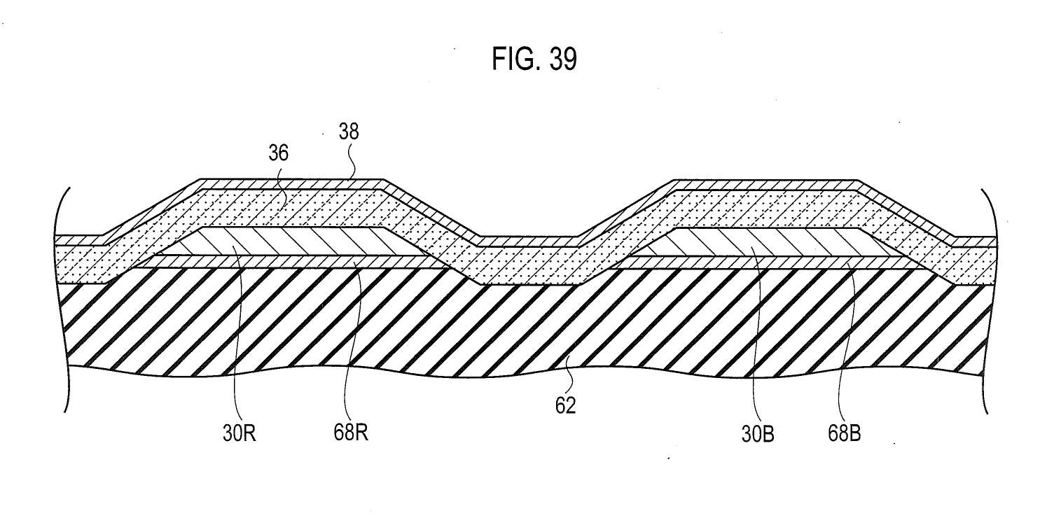

FIG. 38 shows a schematic cross-sectional structure of an organic EL light emitting device according to a sixth embodiment, and FIG. 39 shows a schematic cross-sectional structure of adjoining RB sub-pixel parts.

As shown in FIGS. 38 and 39, the organic EL light emitting device according to the sixth embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; and an upper electrode 38 disposed on the organic EL layer 36. In this case, a sidewall part of the adhesive layers 68R, 68B and a sidewall part of the lower electrodes 30R, 30B have a tapered shape.

Specifically, the sidewall part of the adhesive layers 68R, 68B and the sidewall part of the lower electrodes 30R, 30B has the same cone angle. Although in particular the cone angle is not limited, but may be 30 degrees, for example.

Moreover, a metal layer which is a material for the lower electrode 30 may be molybdenum (Mo).

In the organic EL light emitting device according to the sixth embodiment, the substrate 58 is composed of an Si wafer, a glass, a gas barrier plastic film, etc. In this case, in the organic EL light emitting device according to the basic configuration, the substrate 58 is an Si wafer on which CMOSLSI 600 is formed. Moreover, the substrate 58 may be a glass substrate on which LSI composed of a thin film transistor (TFT) is formed, for example.

Moreover, the insulating layer 62 is a silicon oxide film etc. formed on the surface of the substrate 58, if the substrate 58 is an Si wafer. Moreover, if the substrate 58 is composed of a gas barrier plastic film, a glass substrate, etc., the insulating layer 62 itself can be composed of a plastic film, a glass substrate, etc.

The lower electrode 30 can also be composed of high-reflectivity metals, e.g. Mo, Al, Ag, or Pt. Moreover, the lower electrode 30 may also be composed of alloys (AlCu etc.) composed of the above-mentioned high-reflectivity metals as a main constituent. Moreover, the lower electrode 30 may be an anode material which becomes hole injection material at the time of being oxidized. As metals which become the hole injection material at the time of being oxidized, Mo, V, Ru, InSn, W, etc. are applicable, for example. If the above-mentioned materials are oxidized, it will be respectively become to MoOₓ, VOₓ, RUOₓ, ITO, and WOₓ.

Furthermore, the adhesive layer 68 can be formed of Ti, Cr, TiN, Ni, Ta, W, etc.

Moreover, the upper electrode 38 is composed of metallic thin films (approximately 0.1 nm to approximately 50 nm in thickness), e.g. Al, Ag, and MgAg, or transparent electrodes (metallic oxide film), e.g. ITO, IZO (approximately 1 nm to approximately 500 nm in thickness).

As shown in FIG. 38, in the organic EL light emitting device according to the sixth embodiment, the adhesive layer 68 (e.g., approximately 20 nm in thickness) is disposed on the insulating layer 62, and the lower electrode 30 (e.g., approximately 40 nm in thickness) is disposed on the adhesive layer 68. Furthermore, the organic EL layer 36 (e.g., approximately 100 nm in thickness) is disposed on the lower electrode 30, and the upper electrode 38 is disposed on the organic EL layer 36. The sidewall part of the adhesive layer 68 and the sidewall part of the lower electrode 30 has the same cone angle.

Accordingly, the film thickness of the organic EL layer 36 in the top surface part (main part) of the lower electrode 30 and the film thickness of the organic EL layer 36 in the sidewall part of the lower electrode 30 become a film thickness of the same grade (approximately 100 nm in thickness). Therefore, a short circuit in the sidewall part S of the lower electrode 30 can be prevented.

Moreover, since the driving voltage of the sidewall part of the lower electrode 30 becomes a voltage of the same grade as the driving voltage of the top surface part of the lower electrode 30, if the same driving voltage as the top surface part is applied to the sidewall part, the brightness intensity of the white light hυ_{f} emitted from the top surface part, and the brightness intensity of the white light hυₛ emitted from the sidewall part become a brightness intensity of the same grade. Specifically, a “ratio of contributing to light emission” of the sidewall part becomes relatively lower compared with that of the comparative example 2, thereby improving the optical extraction efficiency.

Although not illustrated, the lower electrode 30G for green is the same as the lower electrodes 30R, 30B.

### (Fabrication Method of Organic EL Light Emitting Device)

A fabrication method of the organic EL light emitting device according to the sixth embodiment includes: preparing the substrate 58; forming the adhesive layers 68R, 68G, 68B on the substrate 58; forming the lower electrodes 30R, 30G, 30B on the adhesive layers 68R, 68G, 68B; forming the sidewall part of the adhesive layers 68R, 68G, 68B and the sidewall part of the lower electrodes 30R, 30G, 30B in a tapered shape; forming the organic EL layer 36 on the lower electrodes 30R, 30G, 30B; and forming the upper electrode 38 on the organic EL layer 36.

The step of forming the sidewall part of the adhesive layer 68R, 68G, 68B and the sidewall part of the lower electrodes 30R, 30G, 30B in a tapered shape may use the step of performing dry etching using fluorochemical gas.

Moreover, the lower electrodes 30R, 30G, 30B can be formed of Mo, and the adhesive layers 68R, 68G, 68B can also be formed of Ti.

Specifically, the sidewall part of the adhesive layers 68R, 68B and the sidewall part of the lower electrodes 30R, 30B has the same cone angle. The method of forming the sidewall part in a tapered shape may be a method of performing dry etching, for example.

As mentioned above, according to the sixth embodiment, the sidewall part of the adhesive layers 68R, 68G, 68B, and the sidewall part of the lower electrodes 30R, 30G, 30B has the same cone angle. Therefore, the film thickness of the organic EL layer 36 on the sidewall part of the lower electrodes 30R, 30G, 30B becomes a film thickness of the same grade as the top surface part of the lower electrodes 30R, 30G, 30B. Accordingly, the coatability on the sidewall part of the lower electrodes 30R, 30G, 30B can be improved, thereby improving the optical extraction efficiency, and preventing occurring of short-circuiting in the sidewall part S.

### Seventh Embodiment

Hereinafter, a seventh embodiment will be described, in particular regarding difference between the sixth embodiment and the seventh embodiment.

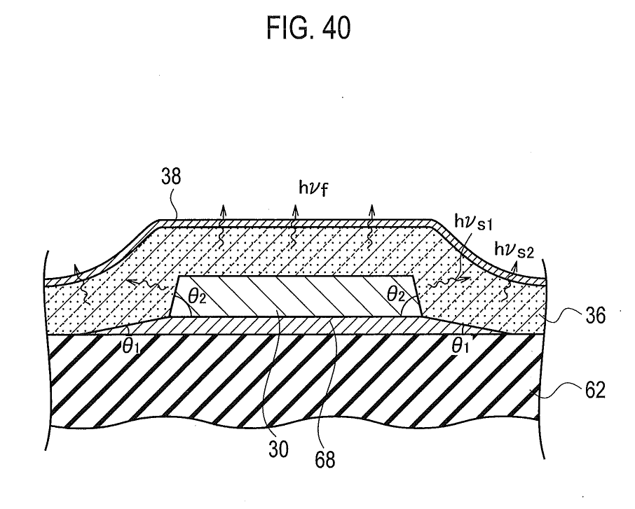

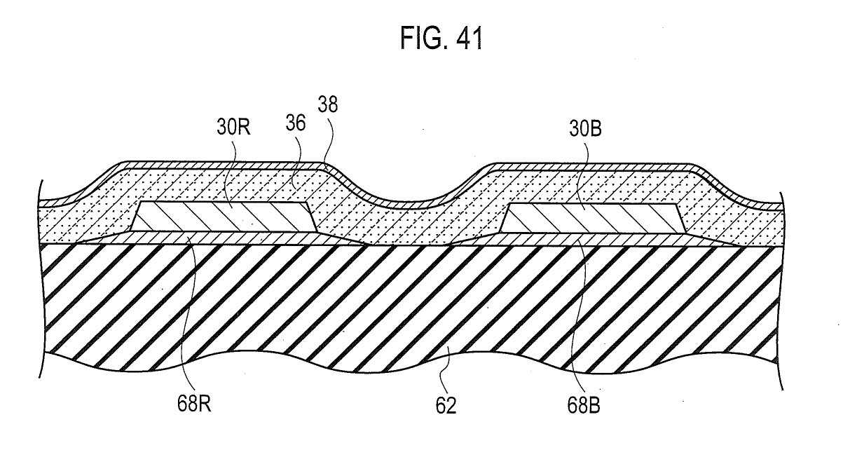

FIG. 40 shows a schematic cross-sectional structure of an organic EL light emitting device according to a seventh embodiment, and FIG. 41 shows a schematic cross-sectional structure of adjoining RB sub-pixel parts.

In the organic EL light emitting device according to the seventh embodiment, a cone angle of the sidewall part of the adhesive layer 68 is smaller than that of the sidewall part of the lower electrode 30, as shown in FIG. 40. The cone angle θ₁ of the sidewall part of the adhesive layer 68 is approximately 10 degrees, for example, and the cone angle θ₂ of the sidewall part of the lower electrode 30 is approximately 80 degrees, for example. Of course, it is not limited to the values of the cone angles θ₁ and θ₂, but what is necessary is just to satisfy a relation of θ₁<θ₂.

Accordingly, the film thickness of the organic EL layer 36 in the sidewall part of the lower electrode 30 becomes thicker than that of the organic EL layer 36 in the top surface part of the lower electrode 30. Therefore, a short circuit in the sidewall part S of the lower electrode 30 can be prevented more securely as compared with the sixth embodiment.

Since the film thickness of the organic EL layer 36 in the sidewall part of the lower electrode 30 becomes thicker than that of the organic EL layer 36 in the top surface part of the lower electrode 30, an electric field applied to the sidewall part of the lower electrode 30 becomes lower than an electric field applied to the top surface part of the lower electrode 30. Therefore, when a driving voltage is applied to the upper electrode 38, the electric field applied to the sidewall part of the lower electrode 30 becomes lower than the electric field applied to the top surface part of the lower electrode 30. Accordingly, the brightness intensity of white light hυₛ₁ emitted from the sidewall part of the lower electrode 30 becomes relatively smaller than the brightness intensity of the white light hυ_{f} emitted from the top surface part of the lower electrode 30.

Moreover, the component of white light hυₛ₁ emitted from the sidewall part of the lower electrode 30, and extracted to the outside is relatively smaller than the component of the white light hυ_{f}. Specifically, the “ratio of contributing to light emission” of the sidewall part of the lower electrode 30 becomes relatively lower than that of the sixth embodiment, thereby further improving the optical extraction efficiency.

Although not illustrated, the lower electrode 30G for green is the same as the lower electrodes 30R, 30B.

### (Fabrication Method of Organic EL Light Emitting Device)

A fabrication method of the organic EL light emitting device according to the seventh embodiment includes: preparing the substrate 58; forming the adhesive layers 68R, 68G, 68B on the substrate 58; forming the lower electrodes 30R, 30G, 30B on the adhesive layers 68R, 68G, 68B; forming the sidewall part of the adhesive layers 68R, 68G, 68B and the sidewall part of the lower electrodes 30R, 30G, 30B in a tapered shape; forming the organic EL layer 36 on the lower electrodes 30R, 30G, 30B; and forming the upper electrode 38 on the organic EL layer 36.

Specifically, the sidewall part of the adhesive layers 68R, 68G, 68B has the cone angle smaller than the sidewall part of the lower electrodes 30R, 30G, 30B.

The lower electrodes 30R, 30G, 30B are formed of molybdenum, the adhesive layers 68R, 68G, 68B are formed of titanium, and then dry etching is performed using fluorochemical gas. Accordingly, since the titanium is harder to be processed than the molybdenum, the sidewall part of the adhesive layers 68R, 68G, 68B is formed in the tapered shape with the cone angle smaller than that of the sidewall part of the lower electrodes 30R, 30G, 30B, as shown in FIG. 41. According to the aforementioned fabrication method, there is also no increase in the process number.

Note that materials of the adhesive layer 68 or the lower electrode 30, and the type of the etching gas are not limited to the examples shown herein. Specifically, since the adhesive layer 68 is harder to be processed than the lower electrode 30, the similar effect can be obtained.

### Modified Example 1

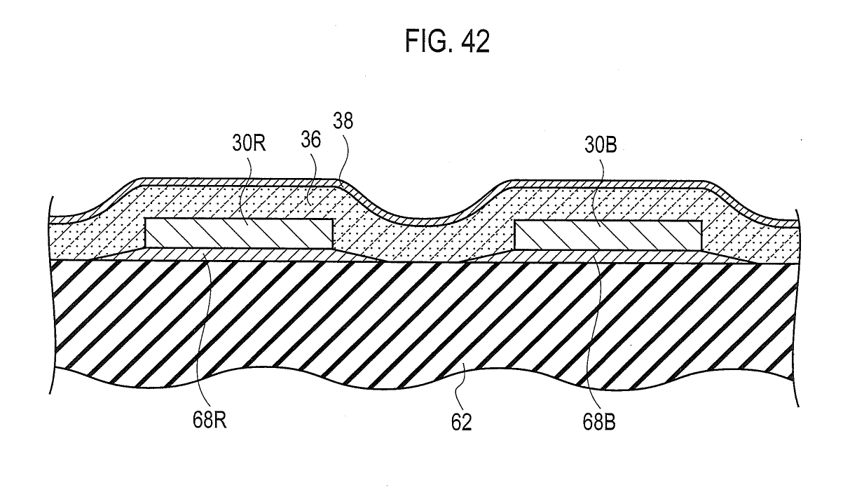

FIG. 42 shows a schematic cross-sectional structure of RB sub-pixel parts adjoining to each other, in an organic EL light emitting device according to a modified example 1 of the seventh embodiment.

As shown in FIG. 42, the sidewall part of the lower electrodes 30R, 30G, 30B has a vertical-shaped cross section. Even in this case, the sidewall part of the adhesive layers 68R, 68G, 68B has a cone angle smaller than that of the sidewall part of lower electrodes 30R, 30G, 30B, as well as the example shown in FIG. 41.

### Modified Example 2

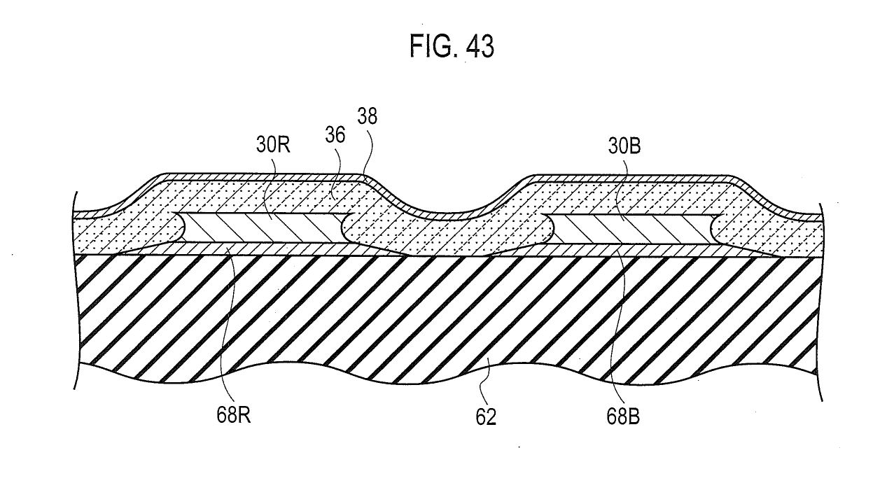

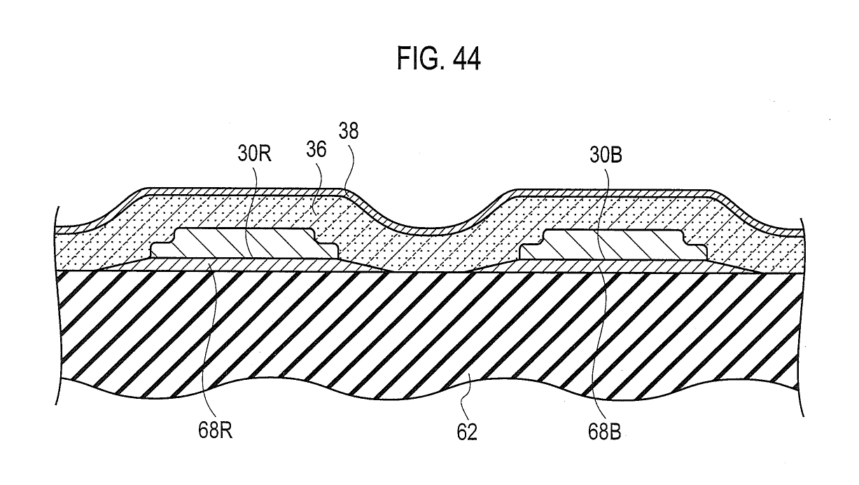

FIG. 43 shows a schematic cross-sectional structure of RB sub-pixel parts adjoining to each other, in an organic EL light emitting device according to a modified example 2 of the seventh embodiment.

As shown in FIG. 43, the sidewall part of the lower electrodes 30R, 30G, 30B has a cross section in a concave shape in an inner side direction. The depth of the concave shape is not particularly limited. Even in this case, the sidewall part of the adhesive layers 68R, 68G, 68B has a cone angle smaller than that of the sidewall part of lower electrodes 30R, 30G, 30B, as well as the example shown in FIG. 41.

### Modified Example 3

FIG. 44 shows a schematic cross-sectional structure of RB sub-pixel parts adjoining to each other, in an organic EL light emitting device according to a modified example 3 of the seventh embodiment.

As shown in FIG. 44, the sidewall part of the lower electrodes 30R, 30G, 30B has a cross section in a step shape. The number of steps of the step shape is not particularly limited. Even in this case, the sidewall part of the adhesive layers 68R, 68G, 68B has a cone angle smaller than that of the sidewall part of lower electrodes 30R, 30G, 30B, as well as the example shown in FIG. 41.

### (Organic EL Light Emitting Device)

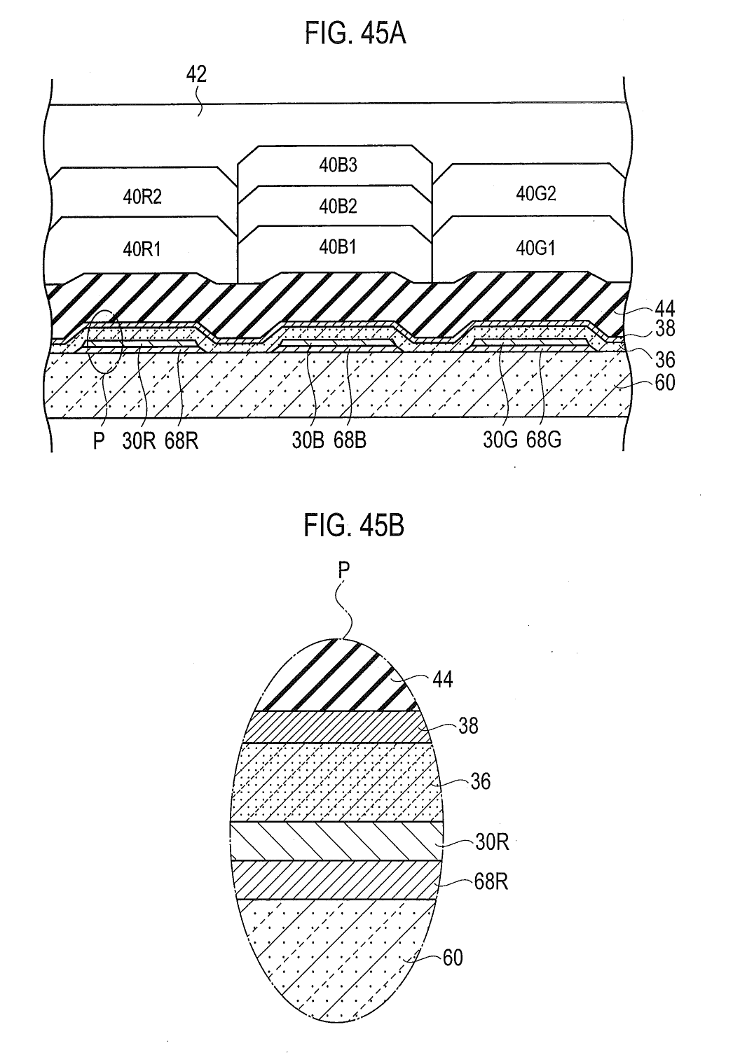

FIG. 45A shows a schematic cross-sectional structure of one pixel part of the organic EL light emitting device according to the seventh embodiment. Moreover, FIG. 45B shows a schematic enlarged structure of a part P shown in FIG. 45A.

Specifically, as shown in FIG. 45, the lower electrodes 30R, 30B, 30G for red, green, and blue are disposed on the semiconductor wafer 60. The lower electrodes 30R, 30B, 30G can be formed of a metal, such as Al, Mo, Ag, and Pt, or alloys thereof (AlCu etc.), for example. Moreover, Ti, Cr, TiN, Ni, Ta, W, etc. may be inserted as an adhesive layer between the lower electrodes 30R, 30B, 30G and the semiconductor wafer 60.

Moreover, the organic EL layer 36 for emitting white light is disposed on the lower electrodes 30R, 30B, 30G, for example. White may be formed in a combination of cyan and yellow.

Furthermore, the upper electrode 38 and the sealing layer 44 for protecting the organic EL device from water or oxygen are disposed on the organic EL layer 36. The upper electrode 38 can be formed of Al, Ag, MgAg, ITO, IZO, etc. A glass, ceramics, etc. are used as materials of the sealing layer 44. Moreover, since the sealing layer 44 acts as a function which dissipates heat to outside, it is preferable to use a sealing layer with higher coefficient of thermal conductivity. The sealing layer 44 can also be formed of polymeric materials including a sulfur atom. Moreover, the sealing layer 44 can be formed of SiNₓ, SiOₓN_{y}, SiOₓ, AlOₓ, etc. Furthermore, the red color resists 40R1, 40R2, the green color resists 40G1, 40G2, the blue color resists 40B1, 40B2, 40B3 are disposed on the sealing layer 44, for example. In this case, if the respective film thicknesses or the respective numbers of layers of the red color resist, the green color resist, and the blue color resist are different from each other, concavity and convexity can occur on the top surfaces of the color resists. Accordingly, the transparent protective film (transparent resist) 42 which does not include the pigment is formed on each color resist for the purpose of planarization.

### (Layered Color Filter)

FIG. 10 shows a schematic plane constitution of the layered color filter mounted on the organic EL light emitting device according to the seventh embodiment having an example of the delta arrangement pattern on the basis of hexagon.

As shown in FIG. 10, in the layered color filter according to the seventh embodiment, the red color filter 40R, the green color filter 40G, and the blue color filter 40B may include a patter on the basis of a hexagon. In this case, as shown in FIG. 10, in each vertex part of the hexagon, the red color filter 40R, the green color filter 40G, and the blue color filter 40B overlap one another. If rectangular is applied as the basic pattern, the adjoining color filters may become the same color. On the other hand, if hexagon is applied as the basic pattern, the color filters adjoining to each other can be arranged to always be mutually different colors. Accordingly, if the basic pattern is the hexagon, it is enabled to prevent the color mixture with more sufficient accuracy, as compared with the case where the basic pattern is rectangular.

### (Cross-Sectional SEM Photograph)

FIG. 18 shows an example of a bird's-eye view surface SEM photograph of the organic EL light emitting device according to the seventh embodiments on which the layered color filter is mounted. FIG. 18 shows an example of which the layered color filter on the basis of a hexagon is disposed on a sub pixel of which the basic pattern is a hexagon.

FIG. 19 shows an example of a cross-sectional SEM photograph of the organic EL light emitting device according to the seventh embodiments on which the layered color filter is mounted. Moreover, FIG. 20 shows an enlarged cross-sectional SEM photograph of the layered color filter portion shown in FIG. 19, and FIG. 21 shows a detailed explanatory diagram of the layered color filter portion shown in FIG. 20. FIG. 21 is a photograph in which border lines are added to the photograph of FIG. 20.

As shown in FIG. 19, the organic EL layer 36 is laminated via the lower electrode 30 on the CMOSLSI 600, and the color filter 40 and the transparent protective film 42 are further disposed on the organic EL layer 36 via the sealing layer 44.

As shown in FIG. 21, a tip of the green color resist 40G1 overlaps on a tip of the blue color resist 40B1. Similarly, the respective tips overlap one another in sequence of the green color resist 40G1, the blue color resist 40B2, the green color resist 40G2, and the blue color resist 40B3. The transparent protective film 42 is disposed on the green color resist 40G2 and the blue color resist 40B3 for the purpose of planarization.

In this case, since the layer of the blue color resists 40B1, 40B2, 40B3 is the highest layers, the color resists of the mutually different color are alternately overlapped sequentially from the blue color resist 40B1. However, the sequence of overlapping the color resists is limited to the aforementioned example. However, the configuration which overlaps the color resists of the mutually different colors alternately is easy for manufacturing, and can improve the color separating performance, as compared with a configuration which continuously overlaps the color resists of the same color.

As mentioned above, in the seventh embodiment, the sidewall part of the adhesive layers 68R, 68G, 68B has the cone angle smaller than that of the sidewall part of lower electrodes 30R, 30G, 30B. Accordingly, the film thickness of the organic EL layer 36 in the sidewall part of the lower electrodes 30R, 30G, 30B becomes thicker than that of the organic EL layer 36 in the top surface part of the lower electrodes 30R, 30G, 30B. Therefore, occurring of a short circuit can be prevented more securely as compared with the sixth embodiment, and the optical extraction efficiency can be further improved rather as compared with the sixth embodiment.

### Eighth Embodiment

Hereinafter, an eighth embodiment will be described, in particular regarding difference between the eighth embodiment and the sixth and seventh embodiments.

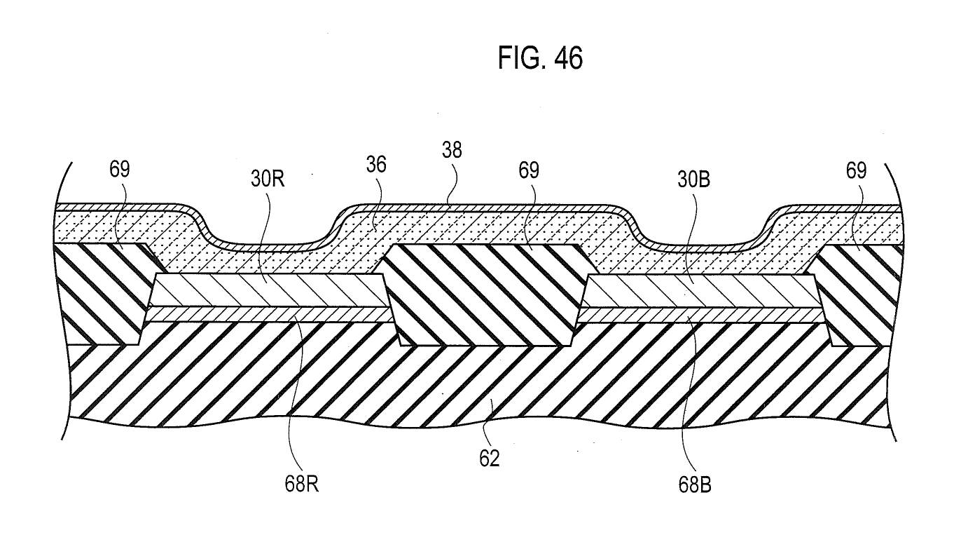

FIG. 46 shows a schematic cross-sectional structure of an organic EL light emitting device according to the eighth embodiment.

As shown in FIG. 46, the organic EL light emitting device according to the eighth embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; an upper electrode 38 disposed on the organic EL layer 36; and an insulating layer 69 disposed between the sidewall part of the lower electrodes 30R and 30B, and the organic EL layer 36.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the eighth embodiment is as follows. First, the lower electrodes 30R, 30G, 30B are formed with the similar method as the sixth embodiment. Subsequently, an oxide film in approximately 80-nm film thickness is formed so that the lower electrodes 30R, 30G, 30B are buried, and then a top surface part of the lower electrodes 30R, 30G, 30B is opened. Accordingly, the insulating layer 69 is formed between the sidewall part of the lower electrodes 30R, 30G, 30B, and the organic EL layer 36. The subsequent steps are the same as the steps of the sixth embodiment.

As mentioned above, the organic EL light emitting device according to the eighth embodiment includes the insulating layer 69 disposed between the sidewall part of the lower electrodes 30R, 30G, 30B and the organic EL layer 36. Accordingly, since the sidewall part of the lower electrodes 30R, 30G, 30B does not contact with the organic EL layer 36, the sidewall part does not contribute to the light-emitting, thereby preventing occurring of a short circuit.

### Ninth Embodiment

Hereinafter, a ninth embodiment will be described, in particular regarding difference between the ninth embodiment and the sixth to eighth embodiments.

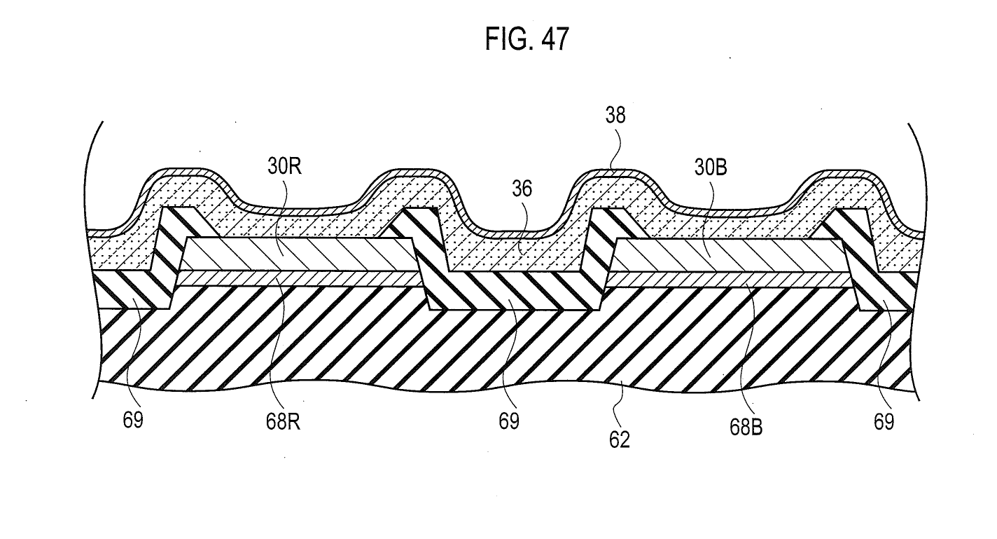

FIG. 47 shows a schematic cross-sectional structure of an organic EL light emitting device according to the ninth embodiment.

As shown in FIG. 47, the organic EL light emitting device according to the ninth embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; an upper electrode 38 disposed on the organic EL layer 36; and an insulating layer 69 having U character-shaped cross-sectional shape is provided between the lower electrodes 30R, 30B.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the ninth embodiment is as follows. First, the lower electrodes 30R, 30G, 30B are formed with the similar method as the eighth embodiment. Subsequently, an oxide film in approximately 40-nm film thickness is formed so that the lower electrodes 30R, 30G, 30B are buried, and then a top surface part of the lower electrodes 30R, 30G, 30B is opened. Accordingly, the insulating layer 69 having U character-shaped cross-sectional shape is formed between the lower electrodes 30R, 30G, 30B. The subsequent steps are the same as the steps of the eighth embodiment.

As mentioned above, in the ninth embodiment, the insulating layer 69 having U character-shaped cross-sectional shape is provided between the lower electrodes 30R, 30B. Therefore, as well as eighth embodiment, the sidewall part of the lower electrodes 30R, 30G, 30B does not contribute to the light-emitting, thereby preventing occurring of a short circuit.

### Tenth Embodiment

Hereinafter, a tenth embodiment will be described, in particular regarding difference between the tenth embodiment and the sixth to ninth embodiments.

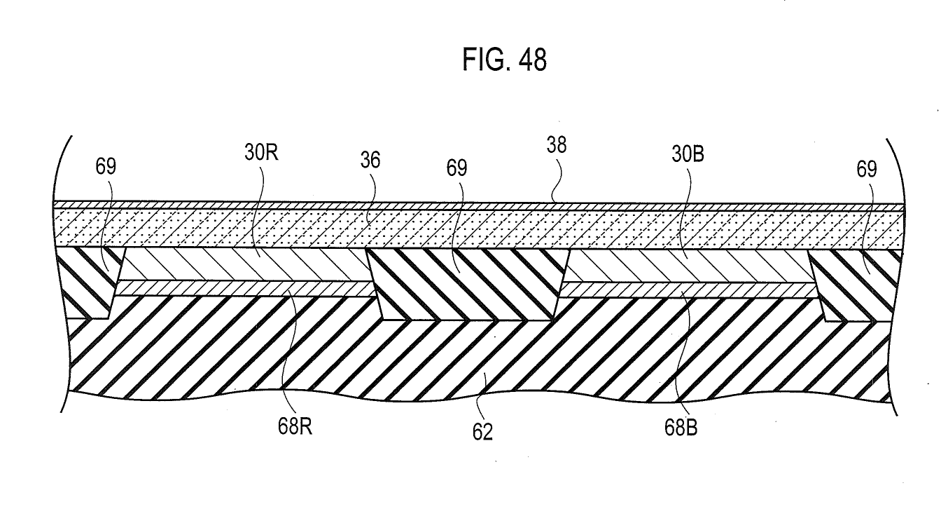

FIG. 48 shows a schematic cross-sectional structure of an organic EL light emitting device according to the tenth embodiment.

As shown in FIG. 48, the organic EL light emitting device according to the tenth embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; and an upper electrode 38 disposed on the organic EL layer 36, wherein a height position of a top surface part of the insulating layer 69 is the same as that of a top surface part of the lower electrodes 30R, 30B.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the tenth embodiment is as follows. First, the lower electrodes 30R, 30G, 30B are formed, and an oxide film is formed, with the similar method as that of the eighth embodiment. Then, the oxide film is subjected to chemical mechanical polishing (CMP) so that the height position of the top surface part of the oxide film is aligned with the same height position as the top surface part of the lower electrodes 30R, 30G, 30B. The subsequent steps are the same as the steps of the eighth embodiment.

### Modified Example

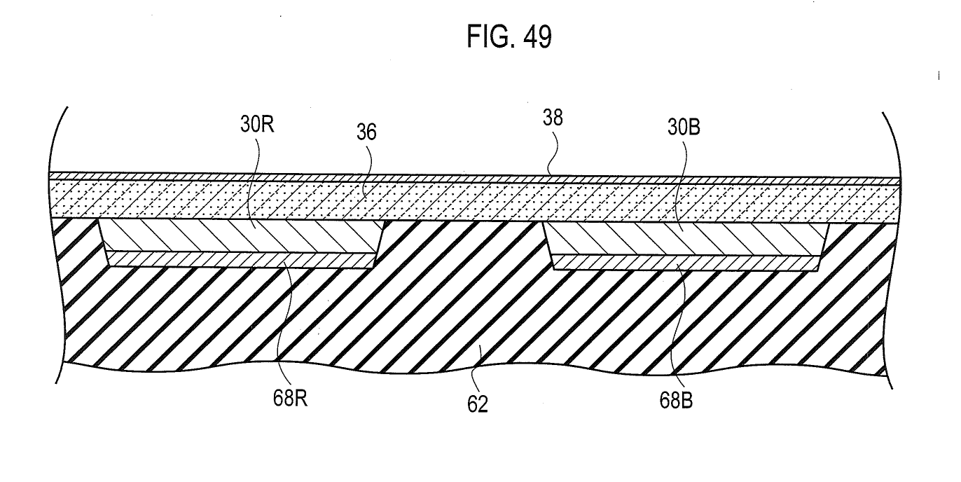

FIG. 49 shows a schematic cross-sectional structure of an organic EL light emitting device according to a modified example of the tenth embodiment.

As shown in FIG. 49, the organic EL light emitting device according to the modified example of the tenth embodiment includes: an insulating layer 62; adhesive layers 68R, 68B disposed on a trench formed on the insulating layer 62; lower electrodes 30R, 30B disposed on the adhesive layers 68R, 68B; an organic EL layer 36 disposed in common on the lower electrodes 30R, 30B; and an upper electrode 38 disposed on the organic EL layer 36, wherein a height position of a top surface part of the insulating layer 62 is the same as that of a top surface part of the lower electrodes 30R, 30B.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the modified example of the tenth embodiment is as follows. First, a trench in a shape of the lower electrode is formed in the insulating layer 62. Subsequently, the trench is filled up, and the adhesive layers 68R, 68B and the lower electrodes 30R, 30B are formed. Next, the lower electrodes 30R, 30B and the adhesive layers 68R, 68B is subjected to CMP so that the height position of the top surface part of the insulating layer 62 is aligned with the same height position as the top surface part of the lower electrodes 30R, 30G, 30B. The subsequent steps are the same as the steps of the eighth embodiment.

As mentioned above, in the tenth embodiment and its modified example, the height position of the top surface part of the insulating layer (62, 69) is the same as that of the top surface part of the lower electrode. Therefore, in addition to the similar effect as the eighth embodiment, the upper electrode can be flatly formed.

### Eleventh Embodiment

Hereinafter, an eleventh embodiment will be described, in particular regarding difference between the eleventh embodiment and the sixth to tenth embodiments.

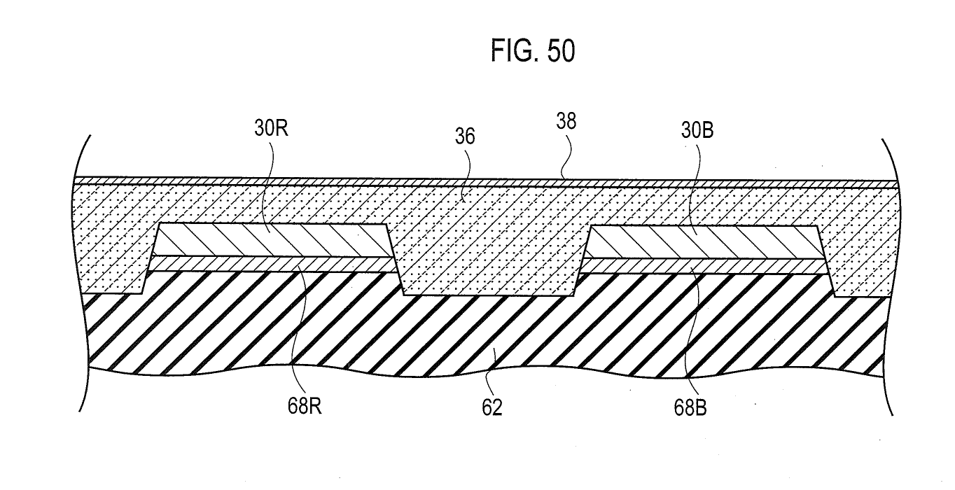

FIG. 50 shows a schematic cross-sectional structure of an organic EL light emitting device according to the eleventh embodiment.

As shown in FIG. 50, the organic EL light emitting device according to the eleventh embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; and an upper electrode 38 disposed on the organic EL layer 36, wherein a constant height of the organic EL layer 36 is formed on a whole region of the top surface part of the lower electrodes 30R, 30B and between the lower electrodes 30R, 30B.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the eleventh embodiment is as follows. First, the lower electrodes 30R, 30G, 30B are formed with the similar method as the eighth embodiment. Subsequently, the constant height of the organic EL layer 36 is disposed on the whole region of the top surface part of the lower electrodes 30R, 30G, 30B, and between the lower electrodes 30R, 30G, 30B. The film thickness of the organic EL layer 36 between the lower electrodes 30R, 30G, 30B is approximately 200 nm, for example, and the film thickness of the organic EL layer 36 on the top surface part of the lower electrodes 30R, 30G, 30B is approximately 100 nm, for example. The subsequent steps are the same as the steps of the eighth embodiment.

As mentioned above, in the eleventh embodiment, the constant height of the organic EL layer 36 is formed on the whole region of the top surface part of the lower electrodes 30R, 30G, 30B and between the lower electrodes 30R, 30G, 30B. Accordingly, since the top surface part of the organic EL layer 36 becomes flat, the upper electrode 38 can be flatly formed, in addition to the similar effect as the eighth embodiment.

### Twelfth Embodiment

Hereinafter, an twelfth embodiment will be described, in particular regarding difference between the twelfth embodiment and the sixth to eleventh embodiments.

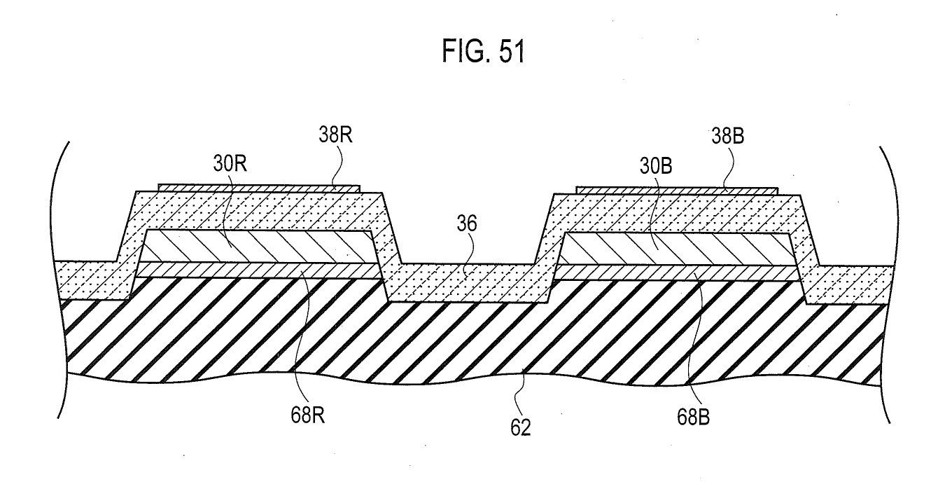

FIG. 51 shows a schematic cross-sectional structure of an organic EL light emitting device according to the twelfth embodiment.

As shown in FIG. 51, the organic EL light emitting device according to the twelfth embodiment includes: a substrate 58; adhesive layers 68R, 68B disposed on the substrate 58; lower electrodes 30R, 30B disposed on the adhesive layers 68R, 68B; an organic EL layer 36 disposed in common on the lower electrodes 30R, 30B; and upper electrodes 38 disposed on the organic EL layer 36, wherein the upper electrodes 38 are formed only on regions facing the top surface part of the lower electrodes 30R 30B.

The shape of the sidewall part of the adhesive layers 68R, 68G, 68B and the shape of the sidewall part of the lower electrodes 30R, 30G, 30B are not particularly limited. Specifically, the shape thereof may be a tapered shape or a nearly vertical shape.

### (Fabrication Method of Organic EL Light Emitting Device)

A fabrication method of the organic EL light emitting device according to the twelfth embodiment is as follows. First, after forming the lower electrodes 30R, 30G, 30B with the similar method as the eighth embodiment, the organic EL layer 36 in approximately 100 nm thick is disposed thereon. The upper electrodes 38 are disposed only on the regions facing the lower electrodes 30R, 30G, 30B on the organic EL layer 36. Such a fabrication method of the upper electrodes 38 is not particularly limited.

As mentioned above, the upper electrodes 38 are formed only on the regions facing the top surface parts of the lower electrodes 30R, 30G, 30B in the twelfth embodiment. Accordingly, the sidewall part of the lower electrodes 30 R, 30G, 30B does not contribute to the light-emitting, thereby obtaining the similar effect as the eighth embodiment.

As explained above, according to the present invention, there can be provided an organic EL light emitting device which can improve optical extraction efficiency while preventing a short circuit, and a fabrication method of such an organic EL light emitting device.

### Other Embodiments

While the present invention is described in accordance with the aforementioned first embodiment and its modified examples 1-7, the aforementioned second to fifth embodiments, and the aforementioned sixth to twelfth embodiment, it should be understood that the description and drawings that configure part of this disclosure are not intended to limit the present invention. This disclosure makes clear a variety of alternative embodiments, working examples, and operational techniques for those skilled in the art.

Such being the case, the present invention covers a variety of embodiments, whether described or not.

### INDUSTRIAL APPLICABILITY

The layered color filter and the organic EL light emitting device on which such a layered color filter is mounted of the present invention are applicable to an organic electroluminescence display device, an organic EL lighting device, etc. More specifically, it is applicable to a micro display, an electronic view finder (EVF) of a mirrorless interchangeable lens camera, a head mounted display, organic integrated circuit fields, flat panel display fields, flexible display electronics fields, transparent electronics fields, etc.

The organic EL light emitting device of the present invention is applicable to an organic electroluminescence display device, an organic EL lighting device, etc. More specifically, it is applicable to a micro display, an electronic view finder (EVF) of a mirrorless interchangeable lens camera, a head mounted display, organic integrated circuit fields, flat panel display fields, flexible display electronics fields, transparent electronics fields, etc.

What is claimed is:

1. An organic EL light emitting device comprising: in one pixel,
a substrate;
a driver circuit disposed on the substrate;
a lower electrode disposed on the driver circuit;
an organic EL layer disposed in common on the lower electrode;
an upper electrode disposed on the organic EL layer; and
a red color filter, a green color filter, and a blue color filter disposed on the upper electrode, wherein
at least one color filter among the red color filter, the green color filter, and the blue color filter is formed as a plurality of thin film layers.

2. The organic EL light emitting device according to claim 1, wherein the number of layers of the blue color filter is larger than the number of layers of the red color filter or the green color filter.

3. The organic EL light emitting device according to claim 2, wherein the red color filter is formed in two layers, the green color filter is formed in two layers, and the blue color filter is formed in three layers.

4. The organic EL light emitting device according to claim 1, wherein a film thickness of each layer of the red color filter, the green color filter, and the blue color filter is equal to or less than 1 micron.

5. The organic EL light emitting device according to claim 4, wherein the film thickness of the blue color filter is thinner than the film thickness of the red color filter or the green color filter.

6. The organic EL light emitting device according to claim 1, wherein a resist pattern of the red color filter, the green color filter, and the blue color filter is equal to or less than 10 microns.

7. The organic EL light emitting device according to claim 1, wherein the color filters adjoining to each other among the red color filter, the green color filter, and the blue color filter overlap one another on an adjoining part in a vertical direction.

8. The organic EL light emitting device according to claim 7, wherein a horizontal width of the adjoining part is 0.8 micron to 1.2 microns.

9. The organic EL light emitting device according to claim 1, wherein the red color filter, the green color filter, and the blue color filter have a patter on the basis of a hexagon, and the red color filter, the green color filter, and the blue color filter overlap one another in each vertex part of the hexagon.

10. The organic EL light emitting device according to claim 7, wherein the color filters of mutually different colors are disposed so as to adjoin to each other.

11. The organic EL light emitting device according to claim 7, wherein the color filters of mutually different color alternately overlap sequentially from a color filter disposed in the highest layer.

12. The organic EL light emitting device according to claim 1, wherein a black color resist for preventing color mixture is disposed on each adjoining part of the red color filter, the green color filter, and the blue color filter.

13. The organic EL light emitting device according to claim 1, wherein a transparent resist is formed on the red color filter, the green color filter, and the blue color filter.

14. The organic EL light emitting device according to claim 1, wherein the upper electrode is formed as a common electrode.

15. An organic EL light emitting device comprising:
a substrate;
a first VIA electrode disposed on the substrate;
a lower electrode disposed on the first VIA electrode;
an organic EL layer disposed in common on the lower electrode;
an upper electrode disposed in common on the organic EL layer; and
a second VIA electrode disposed on the substrate, the second VIA electrode directly contacted to the upper electrode.

16. The organic EL light emitting device according to claim 15, wherein the lower electrode is a metallic material which becomes a hole injection material at the time of being oxidized.

17. The organic EL light emitting device according to claim 15, wherein a metallic oxide film is formed on a surface of the lower electrode, during atmospheric anneal process or UV ozonization process.

18. The organic EL light emitting device according to claim 15, wherein the lower electrode is formed of one of Mo, V, Ru, and InSn.

19. The organic EL light emitting device according to claim 16, wherein the hole injection material is formed on a surface of the lower electrode.

20. The organic EL light emitting device according to claim 19, wherein the hole injection material is a metallic oxide film of the lower electrode.

21. The organic EL light emitting device according to claim 19, wherein a MOS transistor is formed between each sub pixel in a pixel array of the organic EL light emitting device.

22. The organic EL light emitting device according to claim 21, wherein the MOS transistor is a driving transistor for the pixel array.

23. The organic EL light emitting device according to claim 15, wherein the upper electrode is formed as a common electrode.

24. An organic EL light emitting device comprising:
a substrate;
a first VIA electrode disposed on the substrate;
a lower electrode disposed on the first VIA electrode, the lower electrode having a metallic oxide film on a surface thereof;
an organic EL layer disposed in common on the lower electrode;
an upper electrode disposed in common on the organic EL layer; and
a second VIA electrode disposed on the substrate.

25. The organic EL light emitting device according to claim 24, wherein the lower electrode is a metallic material which becomes a hole injection material at the time of being oxidized.

26. The organic EL light emitting device according to claim 24, wherein
the metallic oxide film is formed on the surface of the lower electrode, during atmospheric anneal process or UV ozonization process.

27. The organic EL light emitting device according to claim 24, wherein the lower electrode is formed of one of Mo, V, Ru, and InSn.

28. The organic EL light emitting device according to claim 25, wherein the hole injection material is formed on the surface of the lower electrode.

29. The organic EL light emitting device according to claim 28, wherein the hole injection material is a metallic oxide film of the lower electrode.

30. The organic EL light emitting device according to claim 28, wherein a MOS transistor is formed between each sub pixel in a pixel array of the organic EL light emitting device.

31. The organic EL light emitting device according to claim 30, wherein the MOS transistor is a driving transistor for the pixel array.

32. The organic EL light emitting device according to claim 24, wherein the upper electrode is formed as a common electrode.

33. An organic EL light emitting device comprising:
a substrate;
an adhesive layer disposed on the substrate;
a lower electrode disposed on the adhesive layer;
an organic EL layer disposed in common on the lower electrode; and
an upper electrode disposed on the organic EL layer, wherein
a sidewall part of the adhesive layer and a sidewall part of the lower electrode have a tapered shape.

34. The organic EL light emitting device according to claim 33, wherein the sidewall part of the adhesive layer and the sidewall part of the lower electrode have the same cone angle.

35. The organic EL light emitting device according to claim 33, wherein the cone angle of the sidewall part of the adhesive layer is smaller than that of the sidewall part of the lower electrode.

36. The organic EL light emitting device according to claim 35, wherein the sidewall part of the lower electrode has a vertical-shaped cross section.

37. The organic EL light emitting device according to claim 35, wherein the sidewall part of the lower electrode has a cross section in a concave shape in an inner side direction.

38. The organic EL light emitting device according to claim 35, wherein the sidewall part of the lower electrode has a cross section in a step shape.

39. The organic EL light emitting device according to claim 33, wherein an insulating film is provided between the sidewall part of the lower electrode and the organic EL layer.

40. The organic EL light emitting device according to claim 39, wherein a height position of a top surface part of the insulating film and a height position of a top surface part of the lower electrode are flush with each other.

41. The organic EL light emitting device according to claim 33, wherein a constant height of the organic EL layer is formed on a whole region of a top surface part of the lower electrodes and between the lower electrodes.

42. The organic EL light emitting device according to claim 33, wherein
the upper electrode is formed only on a region facing a top surface part of the lower electrode.

43. The organic EL light emitting device according to claim 33, wherein the upper electrode is formed as a common electrode.

44. An organic EL light emitting device comprising:
a substrate;
an adhesive layer disposed on the substrate;
a lower electrode disposed on the adhesive layer;
an organic EL layer disposed in common on the lower electrode;
an upper electrode disposed on the organic EL layer; and
an insulating film disposed between a sidewall part of the lower electrode and the organic EL layer.

45. An organic EL light emitting device comprising:
a substrate;
an adhesive layer disposed on the substrate;
a lower electrode disposed on the adhesive layer;
an organic EL layer disposed in common on the lower electrode; and
an upper electrode disposed on the organic EL layer, wherein
a constant height of the organic EL layer is formed on a whole region of a top surface part of the lower electrodes and between the lower electrodes.

46. An organic EL light emitting device comprising:
a substrate;
an adhesive layer disposed on the substrate;
a lower electrode disposed on the adhesive layer;
an organic EL layer disposed in common on the lower electrode; and
an upper electrode disposed on the organic EL layer, wherein
the upper electrode is formed only on a region facing a top surface part of the lower electrode.

47. A fabrication method of an organic EL light emitting device, the organic EL light emitting device comprising, in one pixel, a substrate, a driver circuit disposed on the substrate, a lower electrode disposed on the driver circuit, an organic EL layer disposed in common on the lower electrode, an upper electrode disposed on the organic EL layer, and a red color filter, a green color filter, and a blue color filter disposed on the upper electrode, the fabrication method comprising:
applying a color resist to be exposes and developed; and
applying a color resist of the same color thereon again to be exposed and developed, wherein
at least one color filter among the red color filter, the green color filter, and the blue color filter is formed as a plurality of thin film layers.

48. The fabrication method according to claim 47, wherein the blue color filter is formed so that the number of layers of the blue color filter is larger than the number of layers of the red color filter or the green color filter.

49. The fabrication method according to claim 47, wherein the red color filter is formed in two layers, the green color filter is formed in two layers, and the blue color filter is formed in three layers.

50. The fabrication method according to claim 47, wherein the color filters adjoining to each other among the red color filter, the green color filter, and the blue color filter are formed so as to overlap one another on an adjoining part in a vertical direction.

51. The fabrication method according to claim 47, wherein the color filters of mutually different color alternately overlap sequentially from a color filter disposed in the highest layer.

52. A fabrication method of an organic EL light emitting device, the organic EL light emitting device comprising a substrate, a first VIA electrode disposed on the substrate, a lower electrode disposed on the first VIA electrode, an organic EL layer disposed in common on the lower electrode, an upper electrode disposed in common on the organic EL layer, and a second VIA electrode disposed on the substrate, the second VIA electrode directly contacted to the upper electrode, the fabrication method comprising:
forming a dummy lower electrode with the lower electrode on the substrate;
removing the dummy lower electrode;
forming the organic EL layer on the lower electrode; and
forming the upper electrode on the organic EL layer so as to be directly contacted to the second VIA electrode.

53. A fabrication method of an organic EL light emitting device, the fabrication method comprising:
preparing a substrate;
forming a lower electrode on the substrate;
processing a surface of the substrate;
forming an organic EL layer on the lower electrode; and
forming an upper electrode on the organic EL layer.

54. The fabrication method according to claim 53, wherein the lower electrode is a metallic material which becomes a hole injection material at the time of being oxidized.

55. The fabrication method according to claim 53, wherein the step of processing the substrate surface includes oxidizing a surface of the lower electrode during atmospheric anneal process or UV ozonization process.

56. A fabrication method of an organic EL light emitting device, the fabrication method comprising:
preparing a substrate;
forming an adhesive layer on the substrate;
forming a lower electrode on the adhesive layer;
forming a sidewall part of the adhesive layer and a sidewall part of the lower electrode in a tapered shape;
forming an organic EL layer on the lower electrode; and
forming an upper electrode on the organic EL layer.

57. The fabrication method according to claim 56, wherein the step of forming the sidewall part of the adhesive layer and the sidewall part of the lower electrode in a tapered shape includes performing dry etching using fluorochemical gas.

58. The fabrication method according to claim 57, wherein the lower electrode is formed of molybdenum, and the adhesive layer is formed of titanium.

59. The fabrication method according to claim 56, wherein the fabrication method further comprising forming an insulating film between the sidewall part of the lower electrode and the organic EL layer.

60. The fabrication method according to claim 56, wherein in the step of forming the organic EL layer, a constant height of the organic EL layer is formed on a whole region of a top surface part of the lower electrode and between the lower electrodes.

61. The fabrication method according to claim 56, wherein in the step of forming the upper electrode, the upper electrode is formed only on a region facing a top surface part of the lower electrode.

62. A fabrication method of an organic EL light emitting device, the fabrication method comprising:
preparing a substrate;
forming a trenching on the substrate;
forming an adhesive layer in the trench;
filling up the trench and forming a lower electrode on the adhesive layer;
performing polishing process of the adhesive layer and the lower electrode so that a height position of a top surface part of the substrate is aligned with the same height position as a top surface part of the lower electrode;
forming an organic EL layer on the lower electrode; and
forming an upper electrode on the organic EL layer.

63. A layered color filter comprising:
a substrate;
a red color filter disposed on the substrate;
a green color filter disposed on the substrate; and
a blue color filter disposed on the substrate, wherein
at least one color filter among the red color filter, the green color filter, and the blue color filter is formed as a plurality of thin film layers.

64. The layered color filter according to claim 63, wherein the number of layers of the blue color filter is larger than the number of layers of the red color filter or the green color filter.

65. The layered color filter according to claim 63, wherein the red color filter is formed in two layers, the green color filter is formed in two layers, and the blue color filter is formed in three layers.

66. The layered color filter according to claim 63, wherein a film thickness of each layer of the red color filter, the green color filter, and the blue color filter is equal to or less than 1 micron.

67. The layered color filter according to claim 66, wherein the film thickness of the blue color filter is thinner than the film thickness of the red color filter or the green color filter.

68. The layered color filter according to claim 63, wherein a resist pattern of the red color filter, the green color filter, and the blue color filter is equal to or less than 10 microns.

69. The layered color filter according to claim 63, wherein the color filters adjoining to each other among the red color filter, the green color filter, and the blue color filter overlap one another on an adjoining part in a vertical direction.

70. The layered color filter according to claim 69, wherein a horizontal width of the adjoining part is 0.8 micron to 1.2 microns.

71. The layered color filter according to claim 69, wherein the red color filter, the green color filter, and the blue color filter have a patter on the basis of a hexagon, and the red color filter, the green color filter, and the blue color filter overlap one another on each vertex part of the hexagon.

72. The layered color filter according to claim 69, wherein the color filters of mutually different colors are disposed so as to adjoin to each other.

73. The layered color filter according to claim 69, wherein the color filters of mutually different color alternately overlap sequentially from a color filter disposed in the highest layer.

74. The layered color filter according to claim 63, wherein a black color resist for preventing color mixture is disposed on each adjoining part of the red color filter, the green color filter, and the blue color filter.
